(19) United States
(12) Patent Application Publication
(10) Pub. No.: US 2018/0366519 A1
(43) Pub. Date: Dec. 20, 2018

(54) PHOTOELECTRIC CONVERSION DEVICE AND IMAGING UNIT

(71) Applicant: SONY CORPORATION, TOKYO (JP)

(72) Inventors: YOSUKE SAITO, TOKYO (JP); YOSHIAKI OBANA, KANAGAWA (JP); NOBUYUKI MATSUZAWA, TOKYO (JP); MAKOTO HIRATA, TOKYO (JP)

(21) Appl. No.: 16/060,637

(22) PCT Filed: Dec. 13, 2016
(86) PCT No.: PCT/JP2016/087086

§ 371 Date: Jun. 8, 2018

(30) Foreign Application Priority Data
Dec. 28, 2015 (JP) 2015-256622
Mar. 11, 2016 (JP) 2016-048540

(51) Int. Cl. H01L 27/30; H01L 51/44

(52) U.S. Cl. CPC H01L 27/307; H01L 51/0046; H01L 51/442

(57) ABSTRACT

A photoelectric conversion device according to an embodiment of the present disclosure includes: a first electrode and a second electrode facing each other; and a photoelectric conversion layer provided between the first electrode and the second electrode, and including a first organic semiconductor having head (Head)-to-tail (Tail) coupling regioregularity of 95% or more represented by a formula (1) and a second organic semiconductor having head-to-tail coupling regioregularity of 75% or more but less than 95% represented by the formula (1),

### TECHNICAL FIELD

The present disclosure relates to, for example, a photoelectric conversion device using an organic semiconductor material and an imaging unit including the same.

### BACKGROUND ART

Many of practically used solar batteries use an inorganic semiconductor typified by silicon or a compound semiconductor such as cadmium telluride (CdTe), gallium arsenide (GaAs), indium gallium arsenide (InGaAs), or copper indium gallium selenide (CuInGaSe). Solar batteries (inorganic solar batteries) using such an inorganic semiconductor achieves relatively high photoelectric conversion efficiency, and, for example, a silicon solar battery exhibits maximum photoelectric conversion efficiency of about 25%. However, the inorganic solar batteries are fabricated with use of a manufacturing process mainly including a vacuum process, which causes an issue that manufacturing cost is extremely high.

In contrast, solar batteries (organic solar batteries) using an organic semiconductor is manufacturable by a simple coating process, and therefore have advantages of low cost and easy area enlargement, as compared with the solar batteries using the inorganic semiconductor. However, the organic solar batteries have too low photoelectric conversion efficiency to reach a practically usable level. Accordingly, an improvement in device characteristics is desired as a next-generation solar battery in place of the inorganic solar batteries.

For example, NPL 1 reports, as an organic solar battery, a planar pn junction type organic photoelectric conversion device using copper phthalocyanine as a p-type semiconductor material and perylene as an n-type organic semiconductor material. Moreover, for example, NPL 2 reports a bulk heterojunction type organic thin film photoelectric conversion device in which a p-type organic semiconductor material and an n-type organic semiconductor material are blended. In this bulk heterojunction type organic thin film photoelectric conversion device, the p-type organic semiconductor material and the n-type organic semiconductor material are phase-separated, and a uniform pn junction interface is formed in a wide range. This makes it possible to increase photoinduced carrier generation, as compared with the planar pn junction type organic photoelectric conversion device.

Incidentally, the photoelectric conversion devices (organic photoelectric conversion devices) configured using the organic semiconductor as described above are applicable as imaging devices configuring an imaging unit such as a CCD (Charge Coupled Unit) image sensor or a CMOS (Complementary Metal Oxide Semiconductor) image sensor.

In the photoelectric conversion devices used for the solar battery, the image sensor, etc., using, for example, an organic semiconductor material having high carrier mobility makes it possible to further improve device characteristics (for example, quantum efficiency). For example, PTL 1 discloses a method of preparing a 3-substituted polythiophene (P3HT) having a stereoregularity (head (Head)-to-tail (Tail) coupling) ratio of 95% or more, and an electronic device using the 3-substituted polythiophene. Moreover, NPL 3 reports that using a combination of phenyl-C61-methyl butyrate ester (PCBM), P3HT having a high stereoregularity ratio and P3HT having a low stereoregularity ratio makes it possible to suppress aggregation of PCBM.

### CITATION LIST

### Non-Patent Literature

NPL 1: C. W. Tang, Appl.Phys.Lett., 48 (1986) 183-185
NPL 2: N. S. Sariciftci, etc., Appl. Phys.Lett., 62 (1993) 585-587
NPL 3: Campoly-Quileset.al, Organic Electronics, 10 (2009) 1120.

### Patent Literature

PTL 1: Japanese Unexamined Patent Application Publication (Published Japanese Translation of PCT Application) No. 2007-501300

### SUMMARY OF THE INVENTION

PTL 1 and NPL 3 described above report that the higher a stereoregularity ratio P3HT has, the higher carrier mobility is achieved; therefore, P3HT is preferable as a material of a photoelectric conversion device. However, P3HT having a high stereoregularity ratio has high crystallinity; therefore, film surface flatness is low, thereby causing an issue that manufacturing yields are decreased.

It is desirable to provide a photoelectric conversion device and an imaging unit that have high quantum efficiency and allow for an improvement in manufacturing yields.

A photoelectric conversion device according to an embodiment of the present disclosure includes: a first electrode and a second electrode facing each other; and a photoelectric conversion layer provided between the first electrode and the second electrode, and including a first organic semiconductor having head (Head)-to-tail (Tail) coupling stereoregularity of 95% or more represented by the following formula (1) and a second organic semiconductor having head-to-tail coupling stereoregularity of 75% or more but less than 95% represented by the following formula (1).

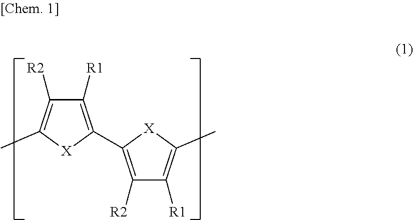

(where R1 and R2 are different from each other, and each are a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof, X is one of chalcogen atoms (oxygen (O), sulfur (S), selenium (Se) and tellurium (Te)) and Group V atoms (nitrogen (N) and phosphorus(P)).)

An imaging unit according to an embodiment of the present disclosure includes pixels each including one or a plurality of photoelectric conversion devices, and includes the photoelectric conversion device according to the foregoing embodiment of the present disclosure as each of the photoelectric conversion devices.

In the photoelectric conversion device according to the embodiment of the present disclosure and the imaging unit according to the embodiment of the present disclosure, the photoelectric conversion layer is formed with use of the first organic semiconductor having head-to-tail coupling stereoregularity of 95% or more represented by the foregoing formula (1) and the second organic semiconductor having head-to-tail coupling stereoregularity of 75% or more but less than 95% also represented by the foregoing formula (1). Accordingly, crystallinity of the first organic semiconductor material is suppressed, and the photoelectric conversion layer having a flat surface is achieved. Moreover, a ratio of Face-on orientation of a polymer including a molecular structure represented by the foregoing formula (1) in the photoelectric conversion layer is enhanced.

According to the photoelectric conversion device of the embodiment of the present disclosure and the imaging unit of the embodiment of the present disclosure, the photoelectric conversion layer is configured with use of the first organic semiconductor having head-to-tail coupling stereoregularity of 95% or more represented by the foregoing formula (1) and the second organic semiconductor having head-to-tail coupling stereoregularity of 75% or more but less than 95% also represented by the foregoing formula (1), which makes it possible to flatten the surface of the photoelectric conversion layer. Moreover, the ratio of Face-on orientation of a polymer including the molecular structure represented by the foregoing formula (1) in the photoelectric conversion layer is enhanced, which makes it possible to improve carrier mobility. This makes it possible to provide a photoelectric conversion device having improved manufacturing yields and improved quantum efficiency and an imaging unit including the same. It is to be noted that effects described herein are not necessarily limited, and any of effects described in the present disclosure may be included.

### BRIEF DESCRIPTION OF THE DRAWINGS

FIG. 1 is a cross-sectional view of an example of a schematic configuration of a photoelectric conversion device according to a first embodiment of the present disclosure.

FIG. 2 is a cross-sectional view of another example of the schematic configuration of the photoelectric conversion device according to the first embodiment of the present disclosure.

FIG. 3 is a schematic view of molecular structures of P3HT having a high stereoregularity ratio (A) and P3HT having a low stereoregularity ratio (B).

FIG. 4 is a schematic view of orientation of P3HT in a typical photoelectric conversion layer (A) and orientation of P3HT in a photoelectric conversion layer of the present disclosure (B).

FIG. 5 is a cross-sectional view of a schematic configuration of a photoelectric conversion device (imaging device) according to a second embodiment of the present disclosure.

FIG. 6 is a cross-sectional view of a schematic configuration of a solar battery using the photoelectric conversion device illustrated in FIG. 1, etc.

FIG. 7 is a functional block diagram of an imaging unit using the imaging device illustrated in FIG. 5 as a pixel.

FIG. 8 is a block diagram illustrating a schematic configuration of an electronic apparatus using the imaging unit illustrated in FIG. 7.

### MODES FOR CARRYING OUT THE INVENTION

In the following, some embodiments of the present disclosure are described in detail with reference to the drawings. It is to be noted that description is given in the following order.
1. Embodiment (an example of a solar battery including a photoelectric conversion layer that is formed with use of two kinds of P3HTs having different stereoregularity ratios)
   1-1. Basic Configuration
   1-2. Manufacturing Method
   1-3. Workings and Effects
2. Second Embodiment (an example of an imaging device)
   2-1. Basic Configuration
   2-2. Manufacturing Method
   2-3. Workings and Effects
3. Application Examples
4. Examples

### 1. EMBODIMENT

### (1-1. Basic Configuration)

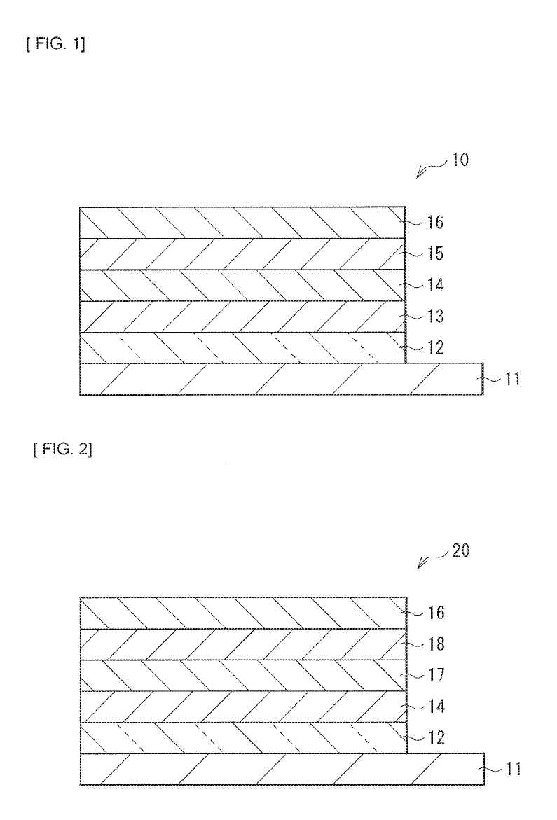

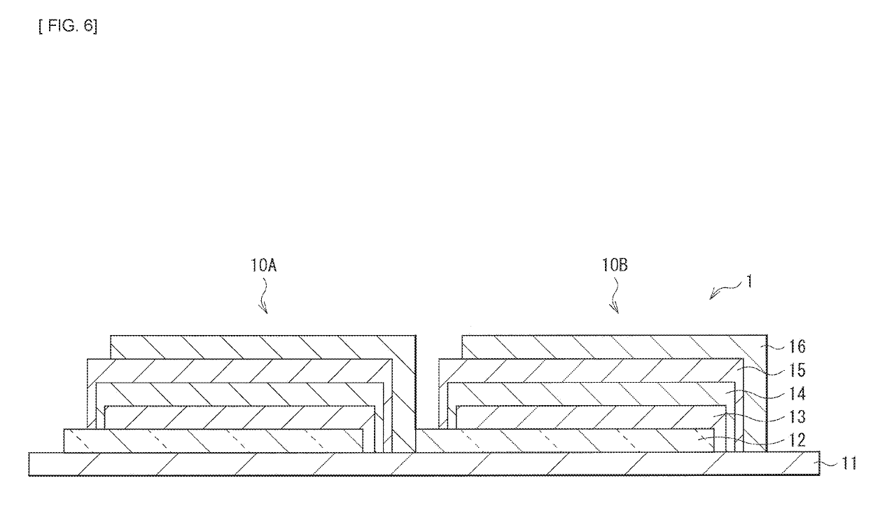

FIG. 1 illustrates an example of a cross-sectional configuration of a photoelectric conversion device (a photoelectric conversion device 10) according to a first embodiment of the present disclosure. The photoelectric conversion device 10 is applied to, for example, a solar battery (a solar battery 1, refer to FIG. 6). The photoelectric conversion device 10 has a configuration in which a transparent electrode 12, a hole transport layer 13, an organic photoelectric conversion layer 14, an electron transport layer 15, and a counter electrode 16 are stacked in this order on a substrate 11. In the photoelectric conversion device 10 according to the present embodiment, the organic photoelectric conversion layer 14 is formed including an organic semiconductor material (a first organic semiconductor material) having head (Head)-to-tail (Tail) coupling stereoregularity of 95% or more and an organic semiconductor material (a second organic semiconductor material) having head-to-tail coupling stereoregularity of 75% or more but less than 95%.

The substrate 11 holds respective layers (for example, the organic photoelectric conversion layer 14) configuring the photoelectric conversion device 10, and is, for example, a plate-like member having two main facing surfaces. In the photoelectric conversion device 10 according to the present embodiment, light entering from a side on which the substrate 11 is located is subjected to photoelectric conversion. For this reason, the substrate 11 is preferably configured with use of a material that allows light (light with a wavelength that is to be subjected to photoelectric conversion) to pass therethrough, and it is possible to use, for example, a glass substrate, a resin substrate, etc. In addition, it is preferable to use a transparent resin film in terms of lightness and flexibility.

A material, a shape, a configuration, a thickness, etc. of the transparent resin film are selectable from known ones as appropriate, but, for example, a transparent resin film having transmittance in a visible region (for example, a wavelength ranging from 380 nm to 800 nm) of 80% or more is preferably used. Examples of such a transparent resin film include polyethylene terephthalate (PET), polyethylene naphthalate (PEN), a polyester-based resin film such as modified polyester, a polyethylene (PE) resin film, a polypropylene (PP) resin film, a polystyrene resin film, a polyolefin resin film such as a cyclic olefin-based resin, a vinyl-based resin film such as polyvinyl chloride and polyvinylidene chloride, a polyetheretherketone (PEEK) resin film, a polysulfone (PSF) resin film, a polyethersulfone (PES) resin film, a polycarbonate (PC) resin film, a polyamide resin film, a polyimide resin film, an acrylic resin film, a triacetylcellulose (TAC) resin film, etc.

In addition, it is preferable to use a biaxially oriented polyethylene terephthalate film, a biaxially oriented polyethylene naphthalate film, a polyethersulfone film, and a polycarbonate film in terms of transparency, heat resistance, handling ease, strength, and cost. In particular, the biaxially oriented polyethylene terephthalate film and the biaxially oriented polyethylene naphthalate film of these films are preferable.

For example, in a case where the organic photoelectric conversion layer 14 is formed with use of a coating method, the substrate 11 may be subjected to surface treatment in order to secure wettability and adhesiveness of a coating liquid. Moreover, an easily adhesive layer may be provided. Known technologies of the surface treatment and the easily adhesive layer are usable. Examples of the surface treatment include surface activation treatment such as corona discharge treatment, flame treatment, ultraviolet treatment, high frequency treatment, glow discharge treatment, active plasma treatment, and laser treatment. Moreover, materials of the easily adhesive layer include polyester, polyamide, polyurethane, a vinyl-based copolymer, a butadiene-based copolymer, an acrylic-based copolymer, a vinylidene-based copolymer, an epoxy-based copolymer, etc. Further, in order to suppress transmission of oxygen and water vapor, a barrier coat layer may be formed on a transparent substrate.

It is to be noted that the substrate 11 may not be necessarily used, and the photoelectric conversion device 10 may be configured, for example, by forming the transparent electrode 12 and the counter electrode 16 with the organic photoelectric conversion layer 14 in between.

In a case where the transparent electrode 12 is used as, for example, an anode, preferably, an electrode material that allows light in the visible region to pass therethrough is preferably used. Such a material is, for example, a transparent conductive metal oxide such as indium tin oxide (ITO), SnO₂, or ZnO, metal such as gold (Au), silver (Ag), or platinum (Pt), a metal nanowire, or a carbon nanotube. In addition, a conductive polymer, etc. selected from a group of respective derivatives of polypyrrole, polyaniline, polythiophene, polythienylene vinylene, polyazulene, polyisothianaphthene, polycarbazole, polyacetylene, polyphenylene, polyphenylenevinylene, polyacene, polyphenylacetylene, polydiacetylene, and polynaphthalene may be used as the material of the transparent electrode 12. It is to be noted that the transparent electrode 12 may be formed with use of only one of the foregoing conductive compounds or with use of a combination of two or more of the foregoing conductive compounds.

The hole transport layer 13 efficiently extracts electric charges (herein, holes) generated in the organic photoelectric conversion layer 14. Examples of a material configuring the hole transport layer 13 include PEDOT such as Baytron P (registered trademark) manufactured by Starck-V TECH Ltd., polyaniline and a material doped with polyaniline, a cyan compound described in WO2006/019270, etc. A method of forming the hole transport layer 13 may be any of a vacuum evaporation method and a coating method, but the coating method is preferable, because forming a coating film below the organic photoelectric conversion layer 14 before forming the organic photoelectric conversion layer 14 causes an effect of leveling a coated surface, which makes it possible to reduce an influence of leakage, etc.

It is to be noted that in addition to the hole transport layer 13, an electron block layer may be provided between the transparent electrode 12 and the organic photoelectric conversion layer 14. The electron block layer has a rectification effect that prevents electrons generated at a bulk heterojunction interface of the organic photoelectric conversion layer 14 from flowing toward the transparent electrode 12. The electron block layer is preferably formed with use of a material having a shallower LUMO level than a LUMO level of the n-type semiconductor material configuring the organic photoelectric conversion layer 14. Specific examples of the material configuring the electron block layer include a triarylamine-based compound described in Japanese Unexamined Patent Application Publication No. H05-271166, etc., a metal oxide such as molybdenum oxide, nickel oxide, and tungsten oxide, and the like. Moreover, the electron block layer may be formed with use of the p-type organic semiconductor material used for the organic photoelectric conversion layer 14. It is possible to form the electron block layer by any of a vacuum evaporation method and a coating method, but the coating method is preferable because of the same reason as the hole transport layer 13.

The organic photoelectric conversion layer 14 converts light energy into electrical energy. The organic photoelectric conversion layer 14 has, for example, a bulk heterojunction interface in which a p-type semiconductor material and an n-type semiconductor material are mixed. The p-type semiconductor material relatively serves as an electron donor (a donor), and the n-type semiconductor material relatively serves as an electron acceptor (an acceptor). The organic photoelectric conversion layer 14 provides a setting for dissociation of excitons generated upon absorption of light into free electrons and holes, and specifically, excitons are dissociated into free electrons and holes at an interface between the electron donor and the electron acceptor. In other words, unlike an electrode, the electron donor and the electron acceptor do not simply donate or accept electrons, but donate or accept electrons depending on light reaction.

In the photoelectric conversion device 10 according to the present embodiment, light incident from the transparent electrode 12 through the substrate 11 is absorbed by the electron donor or the electron acceptor at the bulk heterojunction interface of the organic photoelectric conversion layer 14. Excitons thereby generated move to the interface between the electron acceptor and the electron donor, and are dissociated into free electrons and holes. Electric charges generated here are transported to respective different electrodes by diffusion caused by a difference in carrier concentration and an internal electric field caused by a difference in work function between an anode (herein, the transparent electrode 12) and a cathode (herein, the counter electrode 16), and are detected as a photocurrent. Moreover, applying a potential between the transparent electrode 12 and the counter electrode 16 makes it possible to control transport directions of electrons and holes.

The p-type semiconductor materials include various condensed polycyclic aromatic low molecular compounds and conjugated polymers; however, in the present embodiment, a high molecular compound (polymer) having head-to-tail coupling stereoregularity is used. The high molecular compound having stereoregularity is formed, for example, by polymerizing a five-membered ring compound or a six-membered ring compound in which substituent groups different from one another are bound to ring carbon, and preferably has, for example, a average molecular weight of 5000 to 150000 both inclusive. Specifically, the high molecular compound is formed by polymerizing, via, for example, a carbon atom adjacent to a heteroatom, molecules that have a five-membered heterocyclic skeleton and have substituent groups R1 and R2 different from each other, as represented by the following formula (1), for example. Herein, head-to-tail coupling is, for example, coupling between two certain molecules adjacent to each other in which the substituent group R1 in one molecule is located at a position (head) adjacent to a carbon atom forming coupling with the adjacent molecule and the substituent group R1 in the other molecule is located at a position (tail) adjacent to a carbon atom forming coupling with a molecule on a side opposite to the one molecule.

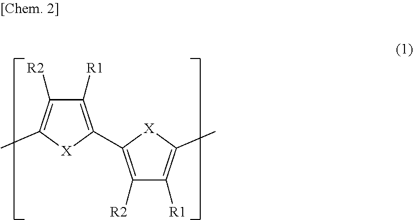

(where R1 and R2 are different from each other, and each are a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof, X is one of chalcogen atoms (oxygen (O), sulfur (S), selenium (Se) and tellurium (Te)) and Group V atoms (nitrogen (N) and phosphorus(P)).)

Specific examples of the organic semiconductor material having head-to-tail coupling stereoregularity include organic semiconductor materials represented by, for example, the following formulas (1-1) and (1-2). It is to be noted that the substituent groups R1 and R2 may be bound to each other to form a ring structure, and in this case, for example, it is only necessary for the organic semiconductor material to have an asymmetric structure as a whole molecule in which substituent groups bound to a ring are different from each other, as represented by the formula (1-2).

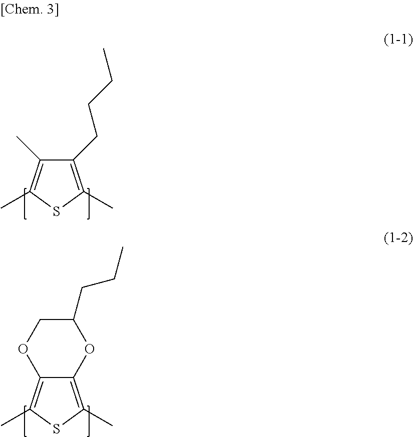

In the present embodiment, the organic photoelectric conversion layer 14 preferably includes at least two kinds, that is, an organic semiconductor material (a first organic semiconductor material) having stereoregularity of 95% or more and an organic semiconductor material (a second organic semiconductor material) having stereoregularity of 75% or more but less than 95% out of the foregoing organic semiconductor materials having head-to-tail coupling stereoregularity. Further, the organic semiconductor material having head-to-tail coupling stereoregularity of 95% or more is preferably included at a ratio of 10 wt % or more of the entire p-type semiconductor material having head-to-tail coupling stereoregularity configuring the organic photoelectric conversion layer 14. This improves flatness of a film surface of the organic photoelectric conversion layer 14.

As the n-type semiconductor material, for example, fullerene derivatives represented by the following formulas (2-1) to (2-7) are preferably used. It is to be noted that the fullerene derivatives represented by the formulas (2-1) to (2-7) are examples, and any other fullerene derivative may be used. Moreover, other than the fullerene derivatives, any material that does not have absorption in the visible region and uses free electrons as carriers transporting electric charges may be used. Examples of such a material include perfluorophthalocyanine, perchlorophthalocyanine, naphthalene tetracarboxylic anhydride, naphthalene tetracarboxylic diimide, perylene tetracarboxylic anhydride, perylene tetracarboxylic diimide, etc. A composition ratio (weight ratio) between the p-type semiconductor material and the n-type semiconductor material included in the organic photoelectric conversion layer 14 is preferably, for example, in a range from 75:25 to 25:75.

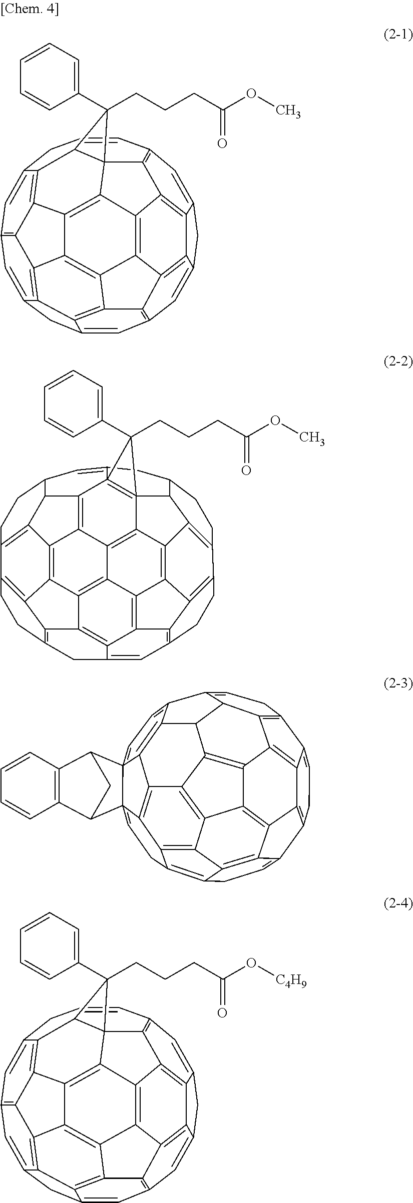

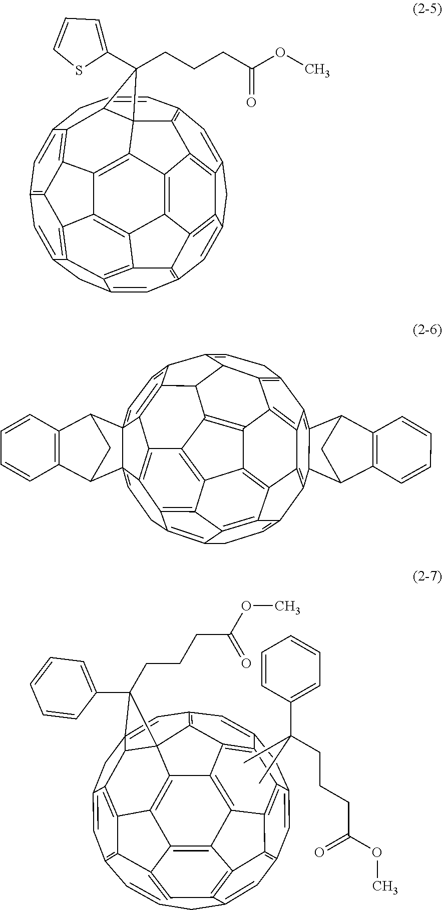

The electron transport layer 15 efficiently extracts electric charges (herein, electrons) generated in the organic photoelectric conversion layer 14. Examples of a material configuring the electron transport layer 15 include octaazaporphyrin and a perfluoro body of the p-type semiconductor material (such as perfluoropentacene and perfluorophthalocyanine). A method of forming the electron transport layer 15 may be one of a vacuum evaporation method and a coating method, but the coating method is preferable.

It is to be noted that in addition to the electron transport layer 15, a hole block layer may be provided between the organic photoelectric conversion layer 14 and the counter electrode 16. The hole block layer has an rectification effect that prevents holes generated at the bulk heterojunction interface of the organic photoelectric conversion layer 14 from flowing toward the counter electrode 16. The hole block layer is preferably formed with use of a material having a deeper HOMO level than a HOMO level of the p-type semiconductor material used for the organic photoelectric conversion layer 14. Specific examples of the material configuring the hole block layer include a phenanthrene-based compound such as bathocuproine, an n-type semiconductor material such as naphthalene tetracarboxylic anhydride, naphthalene tetracarboxylic diimide, perylene tetracarboxylic anhydride, and perylene tetracarboxylic diimide, and an n-type inorganic oxide such as titanium oxide, zinc oxide, and gallium oxide. Moreover, the hole block layer may be formed with use of the n-type semiconductor material used for the organic photoelectric conversion layer 14. In addition, alkali metal compounds such as lithium fluoride (LiF), sodium fluoride (NaF), and cesium fluoride (CsF), and the like are usable. Among these materials, the alkali metal compounds that are further doped with an organic semiconductor molecule may be used. This makes it possible to improve electrical junction of an organic layer (for example, the organic photoelectric conversion layer 14, the electron transport layer 15, the hole block layer, or the like) in contact with the counter electrode 16. The electron block layer may be formed by any of the vacuum evaporation method and the coating method as with the electron transport layer 15, but the coating method is preferable.

In a case where the counter electrode 16 is used as, for example, a cathode, the counter electrode 16 may be formed with use of only materials having conductivity (conductive materials), or may be formed with combined use of, in addition to the conductive material, a resin holding these materials. The conductive material preferably has sufficient conductivity and a work function close to the work function of the n-type semiconductor material to such an extent that a Schottky barrier is not formed upon a junction with the foregoing n-type semiconductor material, and a material resistant to deterioration is more preferably used. Accordingly, metal having a work function deeper by 0 eV to 0.3 eV than LUMO of the n-type semiconductor material used for the organic photoelectric conversion layer 14 is preferably used. Specifically, examples thereof include aluminum (Al), gold (Au), silver (Ag), copper (Cu), indium (In), or an oxide-based material such as zinc oxide, ITO, or titanium oxide.

It is to be noted that it is possible to measure the work function of the foregoing conductive material with use of ultraviolet photoelectron spectroscopy (UPS).

Moreover, the counter electrode 16 may be formed with use of an alloy on an as-needed basis. Examples of the alloy configuring the counter electrode 16 include aluminum alloys such as a magnesium (Mg)/Ag mixture, a Mg/Al mixture, an Al/In mixture, an Al/aluminum oxide (Al₂O₃) mixture, and a lithium(Li)/Al mixture. It is possible to fabricate the counter electrode 16 with use of a method such as evaporation or sputtering of these electrode materials. A thickness of the counter electrode 16 is preferably, for example, in a range from 10 nm to 5 μm, and more preferably in a range from 50 nm to 200 nm.

It is to be noted that in a case where light is transmitted from a side on which the counter electrode 16 is located, for example, it is possible to form the counter electrode 16 having light transparency, for example, by forming a film including the conductive material, such as Al, the Al alloy, Ag, and a Ag compound, suitable as the counter electrode 16 with a small thickness (for example, a thickness of about 1 nm to about 20 nm) and thereafter forming a film including a conductive material having light transparency.

Positions where the hole transport layer 13 and the electron transport layer 15 are provided may be reversed, and in this case, directions to which electrons and holes flow are reversed. Moreover, in a case where the positions are reversed, the electrode materials configuring the transparent electrode 12 and the counter electrode 16 may be changed to materials having a suitable work function for the materials of the respective layers.

Moreover, the photoelectric conversion device according to the present embodiment may have a so-called tandem type configuration in which, for example, a plurality of organic photoelectric conversion layers (herein two layers; the organic photoelectric conversion layer 14 and an organic photoelectric conversion layer 18) are stacked, as illustrated in FIG. 2. Stacking a plurality of organic photoelectric conversion layers in such a manner makes it possible to improve solar light utilization factor (photoelectric conversion efficiency) upon use as a solar battery. In a photoelectric conversion device 20 of the tandem type, the organic photoelectric conversion layer 14 and the organic photoelectric conversion layer 18 are preferably stacked with an electric charge recombination layer 17. In other words, the photoelectric conversion device 20 has a configuration in which the transparent electrode 12, the organic photoelectric conversion layer 14, the electric charge recombination layer 17, the organic photoelectric conversion layer 18, and the counter electrode 16 are stacked in order from a side on which the substrate is located. The organic photoelectric conversion layer 14 and the organic photoelectric conversion layer 18 may absorb light with spectra that are the same as or different from each other.

The electric charge recombination layer 17 serves as an electrode (an intermediate electrode) in the photoelectric conversion device 10, and includes a material having light transparency and conductivity. Such a material is the transparent conductive metal oxide such as ITO, SnO₂, or ZnO, the metal such as gold (Au), silver (Ag), or platinum (Pt), the metal nanowire, or the carbon nanotube mentioned in the foregoing the transparent electrode 12, or the like.

It is to be noted that, in the photoelectric conversion devices 10 and 20 according to the present embodiment, layers other than the foregoing respective layers, for example, a hole injection layer, an electron injection layer, an exciton block layer, a UV absorption layer, a light reflection layer, a wavelength conversion layer, etc. may be formed. In addition, an optical functional layer may be provided. The optical functional layer is used to efficiently receive solar light, for example. Examples of the optical functional layer include an antireflective film, a light concentration layer such as a microlens array, a light diffusion layer that allows light reflected by the counter electrode 16 to be scattered and then enter the organic photoelectric conversion layer 14, or the like.

As the antireflective film, it is possible to provide any of various known antireflective films. To give an example, in a case where a transparent resin film is a biaxially oriented polyethylene terephthalate film, a refractive index of an easily adhesive layer adjacent to the film is set in a range from 1.57 to 1.63, which makes it possible to reduce reflection at an interface between a film substrate and the easily adhesive layer, thereby improving transmittance. A method of adjusting the refractive index is executable by appropriately adjusting a ratio between an oxide sol having a relatively high refraction index such as a tin oxide sol and a cerium oxide sol and a binder resin, and then coating these materials. The easily adhesive layer may include a single layer, but in order to improve adhesiveness, the easily adhesive layer may have a configuration including two or more layers.

Examples of the light concentration layer include a microlens array-like member on a side on which solar light is received, and a so-called light concentration sheet. A combination thereof makes it possible to increase an amount of light received from a specific direction and contrarily reduce incident angle dependence of solar light.

Examples of a microlens array include an array in which a plurality of quadrangular pyramid microlenses having 30 μm on a side and an vertical angle of 90° are two-dimensionally arranged on a light extraction side of a substrate. The one side of the microlens is preferably in a range from 10 μm to 100 μm, for example. In a case where the side is smaller than the range, a diffraction effect is caused to provide a color, and in a case where the side is too large, a thickness of the microlens is increased, which is not preferable.

Moreover, as a light scattering layer, various kinds of anti-glare layers, and a layer in which nanoparticles, nanowires, or the like including metal, various inorganic oxides, or the like are dispersed in a colorless transparent polymer are usable.

### (1-2. Manufacturing Method)

It is possible to manufacture the photoelectric conversion device 10 according to the present embodiment by the following method, for example. First, a thin film including a conductive material (a conductive thin film) is formed on one main surface of the substrate 11 by an optional method, and thereafter, the conductive thin film is patterned to form the transparent electrode 12. It is possible to use a photolithography process, an etching process, etc. for patterning.

Next, the hole transport layer 13 is formed on the transparent electrode 12 by, for example, a coating method, and thereafter, the organic photoelectric conversion layer 14 is formed on the hole transport layer 13. At this occasion, a photoelectric conversion material including the foregoing materials (the organic semiconductor material having head-to-tail coupling stereoregularity of 95% or more, the organic semiconductor material having head-to-tail coupling stereoregularity of 75% or more but less than 95%, and the fullerene derivative (for example, phenyl-C₆₁-methyl butyrate ester (PCBM)) is formed by, for example, a coating method.

Subsequently, the electron transport layer 15 covering the organic photoelectric conversion layer 14 is formed by a suitable technique for a material, and thereafter, the counter electrode 16 is formed on the electron transport layer 15. It is possible to form the counter electrode 16 by, for example, a known suitable method such as an evaporation method.

It is to be noted that coating films that are the hole transport layer 13, the organic photoelectric conversion layer 14, and the electron transport layer 15 formed with use of the coating method are preferably dried in a suitable atmosphere such as a nitrogen gas atmosphere under suitable conditions for materials and solvents.

Specific coating methods include a spin coating method, a casting method, a microgravure coating method, a gravure coating method, a bar coating method, a roll coating method, a wire-bar coating method, a dip coating method, a spray coating method, a screen printing method, a gravure printing method, a flexographic printing method, an offset printing method, an ink-jet printing method, a dispenser printing method, a nozzle coating method, and a capillary coating method. Among these methods, the spin coating method, the flexographic printing method, the gravure printing method, the ink-jet printing method, and the dispenser printing method are preferable.

Solvents used in these film formation methods are not particularly limited, as long as the solvents are able to dissolve the materials. Examples of the solvents include unsaturated hydrocarbon solvents such as toluene, xylene, mesitylene, tetralin, decalin, bicyclohexyl, butylbenzene, sec-butylbenzene, and tert-butylbenzene, halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, and bromocyclohexane, halogenated unsaturated hydrocarbon solvents such as chlorobenzene, dichlorobenzene, and trichlorobenzene, and ether-based solvents such as tetrahydrofuran and tetrahydropyran.

Lastly, the counter electrode 16 and the substrate 11 are bonded together by an insulating sealing material to complete the photoelectric conversion device 10.

### (1-3. Workings and Effects)

As described above, an improvement in device characteristics is desired in the photoelectric conversion device used for a solar battery, an image sensor, etc., and studies has been conducted on the material configuring the photoelectric conversion layer. Using a semiconductor material having high carrier mobility makes it possible to improve, for example, quantum efficiency in the device characteristics, and in recent years, use of 3-substituted polythiophene (P3HT) having stereoregularity has been studied. The higher stereoregularity P3HT has, the higher carrier mobility is achieved; therefore, P3HT is preferable as the material of the photoelectric conversion device. However, P3HT having high stereoregularity has high crystallinity; therefore, in the photoelectric conversion layer using P3HT having high stereoregularity, an aggregate is easily formed on a film surface during film formation. The photoelectric conversion layer has rough surface having low flatness, which causes a device failure resulting from a short circuit, etc. Hence, it is difficult to manufacture a photoelectric conversion device that makes use of high carrier mobility of P3HT to have high quantum efficiency.

In contrast, in the present embodiment, the organic semiconductor material having head-to-tail coupling stereoregularity of 95% or more and the organic semiconductor material having head-to-tail coupling stereoregularity of 75% or more but less than 95% that are both represented by the foregoing formula (1) are used as the material of the organic photoelectric conversion layer 14. A film is formed with use of a mixture of the organic semiconductor material having a high stereoregularity ratio (95% or more) and the organic semiconductor material having a slightly lower stereoregularity ratio (75% or more but less than 95%), which makes it possible to suppress crystallinity of the organic semiconductor material having stereoregularity of 95% or more while keeping high carrier mobility, thereby preventing formation of an aggregate. Thus, it is possible to obtain the organic photoelectric conversion layer 14 having improved flatness.

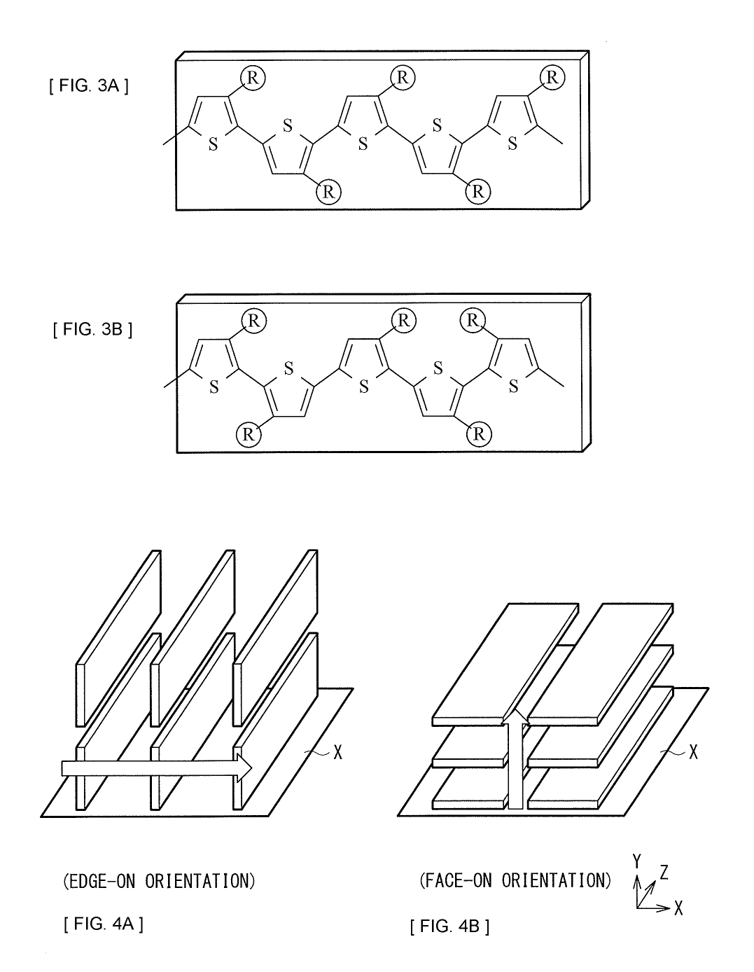

Moreover, in the photoelectric conversion device 10 using the organic photoelectric conversion layer 14 according to the present embodiment, as will be described in detail later, higher quantum efficiency is achieved, as compared with a typical photoelectric conversion device using P3HT having a high head-to-tail coupling stereoregularity ratio (for example, 90%) as the photoelectric conversion material. (A) and (B) of FIG. 3 schematically illustrate molecular structures of P3HT having a high head-to-tail coupling stereoregularity ratio (A) and P3HT having a low head-to-tail coupling stereoregularity ratio (B) as examples of the organic semiconductor materials represented by the foregoing formula (1). P3HT is crystallized in a flat plate shape as illustrated in (A) and (B) of FIG. 3 irrespective of a high or low coupling regioregularity ratio.

In the typical photoelectric conversion device, P3HT easily adopts Edge-on orientation in which, for example, heterocycles are oriented perpendicular to a substrate X (an XZ plane) in the photoelectric conversion layer, as illustrated in (A) of FIG. 4. In contrast, in the photoelectric conversion layer according to the present embodiment formed with use of a mixture of P3HT having head-to-tail coupling stereoregularity of 95% or more and P3HT having head-to-tail coupling stereoregularity of 75% or more but less than 95%, P3HT easily adopts, in its layer, Face-on orientation in which, for example, heterocycles are oriented in parallel to the substrate X (the XZ plane), as illustrated in (B) of FIG. 4. In general, the Edge-on orientation is advantageous to movement of electric charges toward a planar direction of the substrate X (an arrow direction (an X-axis direction)), and the Face-on orientation is advantageous to movement of electric charges toward a direction perpendicular to the substrate X (an arrow direction (a Y-axis direction), that is, a stacking direction of respective layers configuring the photoelectric conversion device. For this reason, in the photoelectric conversion device 10 according to the present embodiment, P3HT easily adopts the Face-on orientation in the organic photoelectric conversion layer 14 as described above; therefore, mobility of electric charges in the organic photoelectric conversion layer 14 is improved, and higher quantum efficiency is achieved.

As described above, in the photoelectric conversion device 10 according to the present embodiment, as the organic photoelectric conversion layer 14, a photoelectric conversion layer is formed with use of the organic semiconductor material having head-to-tail coupling stereoregularity of 95% or more represented by the foregoing formula (1) and the organic semiconductor material having head-to-tail coupling stereoregularity of 75% or more but less than 95% also represented by the foregoing formula (1). This makes it possible to reduce high crystallinity of the organic semiconductor material having head-to-tail coupling stereoregularity of 95% or more and to form the organic photoelectric conversion layer 14 having a flat surface. Moreover, the foregoing organic semiconductor material easily adopts the Face-on orientation that is superior in electric charge movement in the organic photoelectric conversion layer 14, which improves quantum efficiency. This makes it possible to provide the photoelectric conversion device 10 having improved manufacturing yields and improved quantum efficiency and the solar battery 1 (for example, refer to FIG. 6) including the same.

### 2. SECOND EMBODIMENT

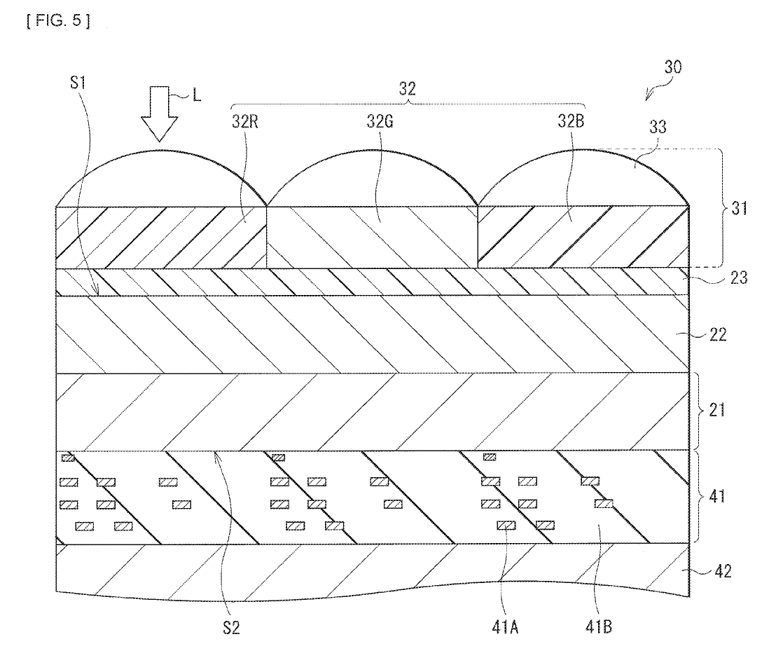

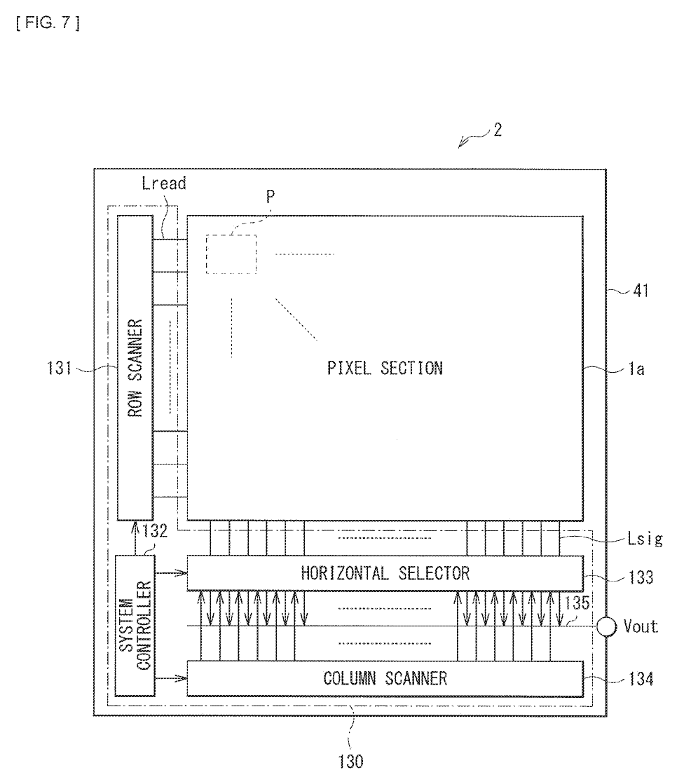

FIG. 5 illustrates a cross-sectional configuration of a photoelectric conversion device (an imaging device 30) according to a second embodiment of the present disclosure. The imaging device 30 configures one pixel (for example, a pixel P) in, for example, an imaging unit (for example, an imaging unit 2) such as a Bayer arrangement type CCD image sensor or CMOS image sensor (both refer to FIG. 7). This imaging device 30 is of a back-side illumination type, and has a configuration in which a light concentration section 31 and a photoelectric converter 22 are provided on a side on which a light incident surface is located of a semiconductor substrate 21, and a multilayer wiring layer 41 is provided on a surface (a surface S2) opposite to a light reception surface (a surface S1).

In the imaging device 30, for example, the photoelectric converter 22 is provided on, for example, the semiconductor substrate 21. The photoelectric converter 22 according to the present embodiment is formed including the organic semiconductor material (the first organic semiconductor material) having head-to-tail coupling stereoregularity of 95% or more and the organic semiconductor material (the second organic semiconductor material) having head-to-tail coupling stereoregularity of 75% or more but less than 95%, as with the organic photoelectric conversion layer 14 according to the foregoing first embodiment.

### (2-1. Basic Configuration)

Specific constituent materials of the semiconductor substrate 21 include compound semiconductors such as cadmium sulfide (CdS), zinc sulfide (ZnS), zinc oxide (ZnO), zinc hydroxide (ZnOH), indium sulfide (InS, In₂S₃), indium oxide (InO), and indium hydroxide (InOH). In addition, n-type or p-type silicon (Si) may be used.

A transfer transistor Tr1 (not illustrated) that transfers a signal electric charge generated in the photoelectric converter 22 to, for example, a vertical signal line Lsig (refer to FIG. 7) is provided in proximity to the surface (the surface S2) of the semiconductor substrate 21. A gate electrode TG1 (not illustrated) of the transfer transistor Tr1 is included in, for example, the multilayer wiring layer 41. The signal electric charge may be one of an electron and a hole generated by photoelectric conversion, but a case where the electron is read out as the signal electric charge is described here as an example.

For example, a reset transistor, an amplification transistor, a selection transistor, etc. are provided together with the foregoing transfer transistor Tr1 in proximity to the surface S2 of the semiconductor substrate 21. Such transistors are, for example, MOSEFTs (Metal Oxide Semiconductor Field Effect Transistors), and configure a circuit for each pixel P. Each circuit may have, for example, a three-transistor configuration including the transfer transistor, the reset transistor, and the amplification transistor, or may have, for example, a four-transistor configuration further including the selection transistor in addition to the these transistors. It is possible to share the transistors other than the transfer transistor among the pixels.

The photoelectric converter 22 includes a p-type semiconductor material and an n-type semiconductor material. The photoelectric converter 22 includes the organic semiconductor material having head-to-tail coupling stereoregularity as described above, and this organic semiconductor material having stereoregularity serves as the p-type semiconductor material. The organic semiconductor material having a stereoregularity ratio is, for example, a high molecular compound formed by polymerizing a five-membered ring compound or a six-membered ring compound in which substituent groups different from one another are bound to ring carbon, and preferably has, for example, a average molecular weight of 5000 to 150000 both inclusive. Specifically, as described in the foregoing first embodiment, the high molecular compound is formed by polymerizing, via, for example, a carbon atom adjacent to a heteroatom, molecules that have a five-membered heterocyclic skeleton and have substituent groups R1 and R2 different from each other, as represented by the formula (1), for example.

Specific examples of the organic semiconductor material having head-to-tail coupling stereoregularity include the organic semiconductor materials represented by, for example, the formulas (1-1) and (1-2) as with the foregoing first embodiment. It is to be noted that the substituent groups R1 and R2 may be bound to each other to form a ring structure, and in this case, it is only necessary for the organic semiconductor material to have an asymmetric structure as a whole molecule in which substituent groups bound to a ring are different from each other, as represented by the formula (1-2).

In the present embodiment, the photoelectric converter 22 includes two kinds, that is, the organic semiconductor material (the first organic semiconductor material) having stereoregularity of 95% or more and the organic semiconductor material (the second organic semiconductor material) having stereoregularity of 75% or more but less than 95%, out of the organic semiconductor materials having head-to-tail coupling stereoregularity, as with the organic photoelectric conversion layer 14 (and the organic photoelectric conversion layer 18) according to the foregoing first embodiment. Further, the organic semiconductor material having head-to-tail coupling stereoregularity of 95% or more is preferably included at a ratio of 10 wt % or more of the entire p-type semiconductor material configuring the photoelectric converter 22. This improves flatness of a film surface of the photoelectric converter 22.

The photoelectric converter 22 includes an n-type semiconductor material in addition to the foregoing organic semiconductor material having head-to-tail coupling stereoregularity. As the n-type semiconductor material, for example, the fullerene derivatives represented by the foregoing formulas (2-1) to (2-7) are preferably used. It is to be noted that the fullerene derivatives represented by the formulas (2-1) to (2-7) are examples of the n-type semiconductor material, and any other fullerene derivative may be used. Moreover, other than the fullerene derivatives, any material that does not have absorption in the visible region and uses free electrons as carriers transporting electric charges may be used. Examples of such a material include n-type semiconductor materials such as perfluorophthalocyanine, perchlorophthalocyanine, naphthalene tetracarboxylic anhydride, naphthalene tetracarboxylic diimide, perylene tetracarboxylic anhydride, and perylene tetracarboxylic diimide. A composition ratio (weight ratio) between the p-type semiconductor material and the n-type semiconductor material included in the photoelectric converter 22 is preferably, for example, in a range from 75:25 to 25:75.

The electrode 23 is formed including a transparent conductive material having light transparency, and is provided on a side on which the light reception surface S1 is located of the photoelectric converter 22. Examples of the transparent conductive material include ITO, indium zinc oxide (IZO), ZnO, indium tin zinc oxide (InSnZnO (α-ITZO)), an alloy of ZnO and Al, etc. This electrode 23 is connected to, for example, a ground, and is prevented from being charged by hole storage. In other words, the photoelectric converter 22 has a configuration sandwiched between the semiconductor substrate 21 serving as a lower electrode and the electrode 23 serving as an upper electrode.

For example, on-chip lenses 33 and color filters 32 are provided as the light concentration section 31 on the electrode 23.

The on-chip lenses 33 have a function of concentrating light onto the photoelectric converter 22. Examples of a lens material include an organic material, a silicon oxide film (SiO₂), etc. In the imaging device 30 of the back-side illumination type, a distance between the on-chip lenses 33 and the light reception surface (the surface S1) of the photoelectric converter 22 is small, which suppresses variations in sensitivity of respective colors and color mixture that are caused depending on an F-number of the on-chip lens 33.

The color filters 32 are provided between the on-chip lenses 33 and the electrode 23, and, for example, one of a red filter 32R a green filter 32G, and a blue filter 32B is provided for each of the pixels P. These color filters 32 are provided in a regular color arrangement (for example, in a Bayer arrangement). Providing such color filters 32 makes it possible for the imaging device 30 to obtain light reception data of colors corresponding to the color arrangement. It is to be noted that, as the color filters 32, a white filter may be provided in addition to the red filter 32R, the green filter 32G, and the blue filter 32B. Moreover, a planarization film may be provided between the electrode 23 and the color filters 32.

The multilayer wiring layer 41 is provided in contact with a top surface and the surface S2 of the semiconductor substrate 21, as described above. The multilayer wiring layer 41 includes a plurality of wiring lines 41A with an interlayer insulating film 41B in between. The multilayer wiring layer 41 is bonded to a supporting substrate 42 including Si, and the multilayer wiring layer 41 is provided between the supporting substrate 42 and the semiconductor substrate 21.

It is possible to manufacture such an imaging device 30 as follows, for example.

### (2-2. Manufacturing Method)

First, the semiconductor substrate 21 including various transistors and peripheral circuits is formed. For example, a Si substrate is used for the semiconductor substrate 21, and transistors such as the transfer transistor T1 and the peripheral circuits such as a logic circuit are provided in proximity to a surface (the surface S2) of the Si substrate. Next, an impurity semiconductor region is formed by ion implantation on a side on which the surface (the surface S2) is located of the Si substrate. Specifically, an n-type semiconductor material region is formed at a position corresponding to each of the pixels P, and a p-type semiconductor material region is formed between respective pixels. Subsequently, the multilayer wiring layer 41 is formed on the surface S2 of the semiconductor substrate 21. In the multilayer wiring layer 41, the plurality of wiring lines 41A are provided with the interlayer insulating film 41B in between, and thereafter, the supporting substrate 42 is bonded to the multilayer wiring layer 41.

Next, the photoelectric converter 22 is formed on a back surface of the semiconductor substrate 21. At this occasion, At this occasion, a photoelectric conversion material including the foregoing materials (the organic semiconductor material having head-to-tail coupling stereoregularity of 95% or more, the organic semiconductor material having head-to-tail coupling stereoregularity of 75% or more but less than 95%, and the fullerene derivative (for example, PCBM) is formed by, for example, a coating method. It is to be noted that a film formation method for the photoelectric converter 22 is not necessarily limited to the coating method, and any other technique, for example, an evaporation method, print technology, etc. may be used.

Next, the electrode 23 is formed on the photoelectric converter 22, and thereafter, for example, the color filters 32 in the Bayer arrangement and the on-chip lenses 33 are formed in order. Thus, the imaging device 30 is completed.

In such an imaging device 30, for example, as the pixel of the imaging unit, signal electric charges (electrons) are obtained as follows. Light L enters the imaging device 30 through the on-chip lens 33, and thereafter, the light L passes through the color filter 32 (32R, 32G, or 32B), etc., and is detected (absorbed) by the photoelectric converter 22. Thereafter, color light of red, green, or blue is subjected to photoelectric conversion. Electrons of electron-hole pairs generated in the photoelectric converter 22 are moved to be stored in the semiconductor substrate 21 (for example, in the n-type semiconductor material region in the Si substrate), and holes are moved to the electrode 23 to be discharged.

In the imaging device 30, a predetermined potential VL (>0 V) is applied to the semiconductor substrate 21, and, for example, a potential VU (<VL) lower than the potential VL is applied to the electrode 23. Accordingly, in an electric charge storage state (an off state of the reset transistor (not illustrated) and the transfer transistor Tr1), electrons of electron-hole pairs generated in the photoelectric converter 22 are guided to the n-type semiconductor material region (the lower electrode) having a relatively high potential of the semiconductor substrate 21. Thus, electrons Eg are extracted from the n-type semiconductor material region to be stored in a storage layer (not illustrated) through a transmission path. Storage of the electrons Eg changes the potential VL of the n-type semiconductor material region brought into conduction with the storage layer. A change amount of the potential VL corresponds to a signal potential.

In a reading operation, the transfer transistor Tr1 is turned to an on state, and the electrons Eg stored in the storage layer are transferred to a floating diffusion (FD, not illustrated). Accordingly, a signal based on a light reception amount of the light L is read out to the vertical signal line Lsig through, for example, a pixel transistor (not illustrated). Thereafter, the reset transistor and the transfer transistor Tr1 are turned to an on state, and the n-type semiconductor material region and the FD are reset to, for example, a power source voltage VDD.

### (2-3. Workings and Effects)

As described above, in the imaging device 30 according to the present embodiment, as the photoelectric converter 22, a photoelectric conversion layer is formed with use of the organic semiconductor material having head-to-tail coupling stereoregularity of 95% or more represented by the foregoing formula (1) and the organic semiconductor material having head-to-tail coupling stereoregularity of 75% or more but less than 95% also represented by the foregoing formula (1). This makes it possible to reduce high crystallinity of the organic semiconductor material having head-to-tail coupling stereoregularity of 95% or more and to form the photoelectric converter 22 having a flat surface. Moreover, the foregoing organic semiconductor material easily adopts the Face-on orientation that is superior in electric charge movement in the photoelectric converter 22, which improves quantum efficiency. This makes it possible to provide the imaging device 30 having improved manufacturing yields and improved quantum efficiency and the imaging unit 2, such as an image sensor, including the same.

Moreover, in general, the imaging device configuring an imaging unit such as a CCD image sensor and a CMOS image sensor includes a large number of inorganic photoelectric conversion devices (photodiodes) formed on a semiconductor substrate, and generates an electrical signal corresponding to incident light. To fabricate such an imaging device, a large-scale semiconductor process is necessary. Therefore, there is an issue that cost reduction is difficult in addition to an extremely large number of processes and difficulty in area enlargement of the semiconductor substrate.

In contrast, in the present embodiment, as described above, the photoelectric converter 22 is formed with use of an organic material that is easily able to form a solution such as the organic semiconductor material having head-to-tail coupling stereoregularity and the fullerene derivative. This makes it possible to form a film with use of a simple method such as a spin coating method and a dipping method. Accordingly, in the present embodiment, it is possible to provide a function equivalent to a typical imaging device including the foregoing photodiode, and to provide the image device 30 that is easily fabricated.

### 3. APPLICATION EXAMPLES

### Application Example 1

FIG. 6 illustrates a cross-sectional configuration of an organic solar battery module (a solar battery 1) using the photoelectric conversion device 10 (or the photoelectric conversion device 20) described in the foregoing first embodiment. In the solar battery 1, two photoelectric conversion devices 10 (10A and 10B) are disposed in a horizontal direction and the counter electrode 16 of the photoelectric conversion device 10A on the left side in the drawing and the transparent electrode 12 of the photoelectric conversion device 10B on the right side are serially coupled to each other, which makes it possible to construct a serially-structured organic solar battery module having a high electromotive force. In the present application example, the two photoelectric conversion devices 10A and 10B are serially coupled to each other; however, the serial connection number is not limited to two, and it is possible to increase the number as appropriate according to specifications of an organic module. It is to be noted that surfaces of the photoelectric conversion devices 10A and 10B may be sealed with a gas-barrier film.

### Application Example 2

FIG. 7 illustrates an entire configuration of a solid-state imaging unit (the imaging unit 2) using the imaging device 30 described in the foregoing embodiment for each of the pixels P. The imaging unit 2 is a CMOS image sensor, and includes a pixel section la as an imaging region and a peripheral circuit section 130 in a peripheral region of the pixel section la on a semiconductor substrate 21. The peripheral circuit section 130 includes, for example, a row scanner 131, a horizontal selector 133, a column scanner 134, and a system controller 132.

The pixel section la includes, for example, a plurality of unit pixels P (each corresponding to the photoelectric conversion device 10) that are two-dimensionally arranged in rows and columns. The unit pixels P are wired with pixel driving lines Lread (specifically, row selection lines and reset control lines) for respective pixel rows, and are wired with vertical signal lines Lsig for respective pixel columns. The pixel driving lines Lread transmit drive signals for signal reading from the pixels. The pixel driving lines Lread each have one end coupled to a corresponding one of output terminals, corresponding to the respective rows, of the row scanner 131.

The row scanner 131 includes a shift register, an address decoder, etc., and is, for example, a pixel driver that drives the respective pixels P of the pixel section 1a on a row basis. Signals outputted from the respective pixels P of a pixel row selected and scanned by the row scanner 131 are supplied to the horizontal selector 133 through the respective vertical signal lines Lsig. The horizontal selector 133 includes, for example, an amplifier, a horizontal selection switch, etc. that are provided for each of the vertical signal lines Lsig.

The horizontal selector 133 includes a shift register, an address decoder, etc., and drives the respective horizontal selection switches of the horizontal selector 133 in order while sequentially performing scanning of those horizontal selection switches. Such selection and scanning performed by the horizontal selector 133 allow the signals of the respective pixels transmitted through the respective vertical signal lines Lsig to be sequentially outputted to a horizontal signal line 135. The thus-outputted signals are transmitted to outside of the semiconductor substrate 21 through the horizontal signal line 135.

A circuit portion including the row scanner 131, the horizontal selector 133, the column scanner 134, and the horizontal signal line 135 may be provided directly on the semiconductor substrate 21, or may be disposed in an external control IC. Alternatively, the circuit portion may be provided in any other substrate coupled by means of a cable or the like.

The system controller 132 receives a clock supplied from the outside of the semiconductor substrate 21, data on instructions of operation modes, and the like, and outputs data such as internal information of the imaging unit 2. Furthermore, the system controller 132 includes a timing generator that generates various timing signals, and performs drive control of peripheral circuits such as the row scanner 131, the horizontal selector 133, and the horizontal selector 133 on the basis of the various timing signals generated by the timing generator.

### Application Example 3

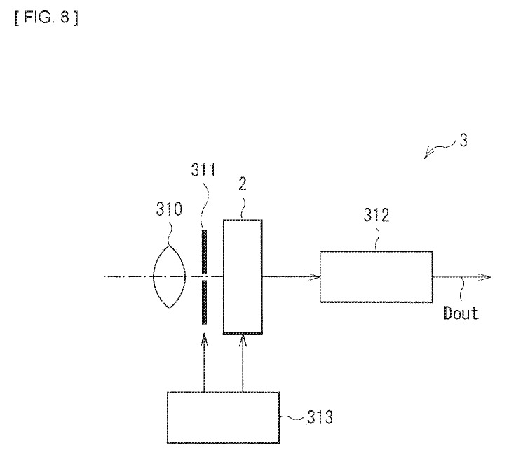

The foregoing imaging unit 2 is applicable to various kinds of electronic apparatuses having imaging functions. Examples of the electronic apparatuses include camera systems such as digital still cameras and video cameras, mobile phones having imaging functions, and the like. FIG. 8 illustrates, for purpose of an example, a schematic configuration of an electronic apparatus 3 (a camera). The electronic apparatus 3 is, for example, a video camera that allows for shooting of a still image or a moving image. The electronic apparatus 3 includes the imaging unit 2, an optical system (an optical lens) 310, a shutter unit 311, a driver 313, and a signal processor 312. The driver 313 drives the imaging unit 2 and the shutter unit 311.

The optical system 310 guides image light (incident light) from an object toward the pixel section la of the imaging unit 2. The optical system 310 may include a plurality of optical lenses. The shutter unit 311 controls a period in which the imaging unit 2 is irradiated with the light and a period in which the light is blocked. The driver 313 controls a transfer operation of the imaging unit 2 and a shutter operation of the shutter unit 311. The signal processor 312 performs various signal processes on signals outputted from the imaging unit 2. A picture signal Dout having been subjected to the signal processes is stored in a storage medium such as a memory, or is outputted to a monitor or the like.

### 4. EXAMPLES

Next, examples of the present disclosure are described in detail.

### Experiment 1

First, as an experiment 1, samples (experimental examples 1 to 12) in which a plurality of kinds of P3HTs having different head-to-tail coupling stereoregularities were combined were fabricated, and average roughness (Ra), crystal orientation, and quantum efficiency (%) were evaluated.

### Experimental Example 1

First, organic semiconductor materials P3HT-1 (having a weight average molecular weight of 47000 and a stereoregularity ratio of 99%) and P3HT-3 (having a weight average molecular weight of 97000 and a stereoregularity ratio of 90%) that each had head-to-tail coupling stereoregularity were used to prepare a chlorobenzene solution including P3HT-1, P3TH-3, and PCBM at a weight ratio of 25:25:50 and a concentration of 35 mg/ml in a N₂-substituted glovebox. Next, a glass substrate provided with an ITO electrode (a lower electrode) was cleaned by UV/ozone treatment, and the substrate was moved into the N₂-substituted glovebox, and was coated with the foregoing chlorobenzene solution by a spin coating method. Thereafter, the substrate was heated by a hot plate at 140° C. for 10 minutes. Thus, the photoelectric conversion layer was formed, and a film thickness thereof was about 250 nm. Next, the substrate was moved into a vacuum evaporator, pressure was reduced to 1×10⁻⁵ Pa or less, and LiF and an AlSiCu alloy were evaporated in this order to form a film having a thickness of 0.5 nm and a film having a thickness of 100 nm, respectively. Thus, an upper electrode was formed. A photoelectric conversion device (the experimental example 1) having a 1 mm×1 mm photoelectric conversion region was fabricated by the above fabricating method.

### Experimental Example 2

A photoelectric conversion device (the experimental example 2) was fabricated with use of a method similar to the experimental example 1, except that as organic semiconductor materials having head-to-tail coupling stereoregularity, P3HT-2 (having a weight average molecular weight of 82000 and a stereoregularity ratio of 99%) and P3HT-3 were used, and a chlorobenzene solution including P3HT-2, P3TH-3, and PCBM at a weight ratio of 25:25:50 and a concentration of 35 mg/ml was used.

### Experimental Example 3

A photoelectric conversion device (the experimental example 3) was fabricated with use of a method similar to the experimental example 1, except that as organic semiconductor materials having head-to-tail coupling stereoregularity, P3HT-1 and P3HT-4 (having a weight average molecular weight of 75000 and a stereoregularity ratio of 90%) were used, and a chlorobenzene solution including P3HT-1, P3TH-4, and PCBM at a weight ratio of 5:45:50 and a concentration of 35 mg/ml was used.

### Experimental Example 4

A photoelectric conversion device (the experimental example 4) was fabricated with use of a method similar to the experimental example 3, except that a chlorobenzene solution including P3HT-1, P3TH-4, and PCBM at a weight ratio of 15:35:50 and a concentration of 35 mg/ml was used.

### Experimental Example 5

A photoelectric conversion device (the experimental example 5) was fabricated with use of a method similar to the experimental example 3, except that a chlorobenzene solution including P3HT-1, P3TH-4, and PCBM at a weight ratio of 25:25:50 and a concentration of 35 mg/ml was used.

### Experimental Example 6

A photoelectric conversion device (the experimental example 6) was fabricated with use of a method similar to the experimental example 3, except that a chlorobenzene solution including P3HT-1, P3TH-4, and PCBM at a weight ratio of 35:15:50 and a concentration of 35 mg/ml was used.

### Experimental Example 7

A photoelectric conversion device (the experimental example 7) was fabricated with use of a method similar to the experimental example 3, except that a chlorobenzene solution including P3HT-1, P3TH-4, and PCBM at a weight ratio of 45:5:50 and a concentration of 35 mg/ml was used.

### Experimental Example 8

A photoelectric conversion device (the experimental example 8) was fabricated with use of a method similar to the experimental example 1, except that a chlorobenzene solution including P3HT-1 and PCBM at a weight ratio of 50:50 and a concentration of 35 mg/ml was used.

### Experimental Example 9

A photoelectric conversion device (the experimental example 9) was fabricated with use of a method similar to the experimental example 1, except that a chlorobenzene solution including P3HT-2 and PCBM at a weight ratio of 50:50 and a concentration of 35 mg/ml was used.

### Experimental Example 10

A photoelectric conversion device (the experimental example 10) was fabricated with use of a method similar to the experimental example 1, except that a chlorobenzene solution including P3HT-3 and PCBM at a weight ratio of 50:50 and a concentration of 35 mg/ml was used.

### Experimental Example 11

A photoelectric conversion device (the experimental example 11) was fabricated with use of a method similar to the experimental example 1, except that a chlorobenzene solution including P3HT-5 (prepared by oxidative polymerization of a 3-hexylthiophene monomer with use of FeC13, and having a weight average molecular weight of 88000 and a stereoregularity ratio of 60%) and PCBM at a weight ratio of 50:50 and a concentration of 35 mg/ml was used.

### Experimental Example 12

A photoelectric conversion device (the experimental example 12) was fabricated with use of a method similar to the experimental example 1, except that a chlorobenzene solution including P3HT-1, P3TH-5, and PCBM at a weight ratio of 25:25:50 and a concentration of 35 mg/ml was used.

Each of flatness, crystal orientation, and quantum efficiency (%) of the photoelectric conversion layers in the foregoing experimental examples 1 to 12 was evaluated. Respective evaluations were performed as follows. First, as evaluation of the flatness, a 10 μm×10 μm square region of a surface shape of a coating film before evaporation of the upper electrode was measured with use of an atomic force microscope (VN-8010 manufactured by keyence Corporation) to calculate average roughness (Ra) of the surface. As evaluation of crystal orientation, crystal orientation of the coating film before evaporation of the upper electrode was evaluated with use of an X-ray diffractometer (RINT-TTR2 manufactured by Rigaku Corporation). Specifically, upon irradiation with a Kα ray of copper, a signal having a peak around a diffraction angle of 5.5° derived from a P3HT (100) plane and a signal having a peak around a diffraction angle of 23.5° derived from a P3HT (010) plane were obtained. The former signal shows presence of P3HT Edge-on oriented with respect to the substrate, and the latter signal shows presence of P3HT Face-on oriented with respect to the substrate. As an indicator of a ratio of the Face-on oriented P3HT to the Edge-on oriented P3HT, a value resulting from dividing peak intensity of the latter signal by peak intensity of the former signal was regarded as evaluation of crystal orientation (an XRD intensity ratio of P3HT (010) plane/(100) plane). As evaluation of the quantum efficiency, an external quantum efficiency spectrum of each of the fabricated photoelectric conversion devices was measured within a range from 350 nm to 850 nm with use of a spectral sensitivity measurement unit manufactured by Bunkoukeiki Co., Ltd. Table 1 summarizes the p-type semiconductor materials and n-type semiconductor material used in the experimental examples 1 to 12 and mixture ratios thereof, and evaluation results of the average roughness (Ra), the crystal orientation, and the quantum efficiency (%).

TABLE 1

| | p-type | | | Mixture | | XRD | Quantum |
|---|---|---|---|---|---|---|---|
| | Semiconductor | | n-type | Ratio | Ra | Intensity | Efficiency |
| | p1 | p2 | Semiconductor | (p1:p2:n) | (nm) | Ratio | (%) |
| Experimental | P3HT-1 | P3HT-3 | PCBM | 25:25:50 | <1 | 0.081 | 60 |
| Example 1 | rr = 99% | rr = 90% | | | | | |
| | Mw = 47K | Mw = 97K | | | | | |
| Experimental | P3HT-2 | P3HT-3 | PCBM | 25:25:50 | <1 | 0.12 | 60 |
| Example 2 | rr = 99% | rr = 90% | | | | | |
| | Mw = 82K | Mw = 97K | | | | | |
| Experimental | P3HT-1 | P3HT-4 | PCBM | 5:45:50 | <1 | 0.077 | 55 |
| Example 3 | rr = 99% | rr = 90% | | | | | |
| | Mw = 47K | Mw = 75K | | | | | |
| Experimental | P3HT-1 | P3HT-4 | PCBM | 15:35:50 | <1 | 0.097 | 58 |
| Example 4 | rr = 99% | rr = 90% | | | | | |
| | Mw = 47K | Mw = 75K | | | | | |
| Experimental | P3HT-1 | P3HT-4 | PCBM | 25:25:50 | <1 | 0.11 | 58 |
| Example 5 | rr = 99% | rr = 90% | | | | | |
| | Mw = 47K | Mw = 75K | | | | | |
| Experimental | P3HT-1 | P3HT-4 | PCBM | 35:15:50 | <1 | 0.13 | 60 |
| Example 6 | rr = 99% | rr = 90% | | | | | |
| | Mw = 47K | Mw = 75K | | | | | |
| Experimental | P3HT-1 | P3HT-4 | PCBM | 45:5:50 | <1 | 0.10 | 56 |
| Example 7 | rr = 99% | rr = 90% | | | | | |
| | Mw = 47K | Mw = 75K | | | | | |
| Experimental | P3HT-1 | — | PCBM | 50:0:50 | >10 | 0.058 | 51 |
| Example 8 | rr = 99% | | | | | | |
| | Mw = 47K | | | | | | |
| Experimental | P3HT-2 | — | PCBM | 50:0:50 | >10 | 0.061 | Evaluation |
| Example 9 | rr = 99% | | | | | | Failed |
| | Mw = 82K | | | | | | |
| Experimental | P3HT-3 | — | PCBM | 50:0:50 | <1 | 0.055 | 45 |
| Example 10 | rr = 90% | | | | | | |
| | Mw = 97K | | | | | | |
| Experimental | P3HT-5 | — | PCBM | 50:0:50 | <1 | <0.01 | 5.6 |
| Example 11 | rr = 60% | | | | | | |
| | Mw = 88K | | | | | | |
| Experimental | P3HT-1 | P3HT-5 | PCBM | 25:25:50 | <1 | 0.052 | 42 |
| Example 12 | rr = 99% | rr = 60% | | | | | |
| | Mw = 82K | Mw = 88K | | | | | |

In the experimental example 8 in which P3HT-1 having a head-to-tail coupling stereoregularity ratio of 99% was used alone, low quantum efficiency was indicated, and in the experimental example 9 in which P3HT-2 having a stereoregularity ratio of 99% was used alone, evaluation as a device was failed. In contrast, in the experimental examples 1 to 7 in which the photoelectric conversion layer was formed with use of the organic semiconductor material having head-to-tail coupling stereoregularity of 95% or more and the organic semiconductor material having head-to-tail coupling stereoregularity of 75% or more but less than 95% (herein, 90%), high quantum efficiency was achieved. It is to be noted that in the experimental example 8 and the experimental example 9, as can be seen from the value of the average roughness (Ra), an aggregate was formed upon film formation by coating due to high crystallinity of P3HT-1 and P3HT-2, thereby deteriorating the flatness of the film surface. In particular, in the experimental example 9, evaluation as the device was failed. In contrast, in the experimental examples 1 to 7, the value of the average roughness (Ra) was less than 1 nm. It is considered that the reason for this is that high crystallinity of P3HT-1 and P3HT-2 was reduced by mixing P3HT-3 or P3HT-4 having a stereoregularity ratio of 90% to P3HT-1 and P3HT-2 having a stereoregularity ratio of 99% to prevent aggregation, thereby improving flatness of a surface of the photoelectric conversion layer. Moreover, as can be seen from the XRD intensity ratio, in the experimental example 8 and the experimental example 9, a large amount of Edge-on oriented P3HT that was disadvantageous in carrier transport in a vertical direction was present. In contrast, it was found that in the experimental examples 1 to 7, Face-on oriented P3HT that was advantageous in the carrier transport in the vertical direction was increased, and Edge-on oriented P3HT that was disadvantageous in the carrier transport in the vertical direction was decreased. Hence, in the experimental examples 1 to 7, it is considered that an improvement in the flatness of the surface and an increase in Face-on oriented P3HT made it possible to exert high electric charge (herein, hole) mobility of P3HT-1 and P3HT-2.

Moreover, the experimental examples 1 to 7 achieved higher quantum efficiency than the experimental example 10 in which P3HT-3 having stereoregularity decreased to reduce high crystallinity was used alone. Further, quantum efficiency in the experimental example 11 in which P3HT-5 having the lowest stereoregularity ratio was used alone was extremely low. The reason for this was inferred from the XRD intensity ratio. As can be seen from the XRD intensity ratio, in the experimental examples 1 to 7, Face-on oriented P3HT that was advantageous in carrier transport in the vertical direction was increased, and Edge-on oriented P3HT that was disadvantageous in the carrier transport in the vertical direction was decreased. It was considered that, for this reason, the experimental examples 1 to 7 achieved high quantum efficiency.

It is to be noted that in the experimental example 12 in which P3HT-1 and P3HT-5 having a stereoregularity ratio of 60% were used, flatness of the surface of the photoelectric conversion layer was quantified, but the XRD intensity ratio was lower than that in the experimental examples 1 to 7, and the quantum efficiency was also low. Hence, as the organic semiconductor material having head-to-tail coupling stereoregularity used together with the organic semiconductor material having head-to-tail coupling stereoregularity of 95% or more, an organic semiconductor material having a stereoregularity ratio of larger than 60%, for example, 75% or more is preferably used.

Grounds that a lower limit of stereoregularity of the second kind of P3HT is 75% are as follows. The film thickness of the organic photoelectric conversion layer is generally from 50 nm to 300 nm, and this film thickness roughly corresponds to a transport distance of free carriers resulting from dissociation, at a bulk heterojunction interface, of excitons generated by light absorption. In consideration of a case where a device is in a short-circuit state, an internal electric field is hardly present, and driving force of carriers are dominated by a diffusion phenomenon. If the generated free carriers are able to reach an electrode before being deactivated by recombination reaction, etc., efficient carrier transport is achievable. In other words, in order to achieve efficient carrier transport, it is important that a diffusion length of carriers is equal to or larger than the film thickness of the organic photoelectric conversion layer. Herein, the diffusion length (1) is represented by the following expression using a diffusion coefficient (D) and a carrier lifetime (t).

[Math. 1]

1=\sqrt{D×t} (1)

In contrast, mobility of a conjugated polymer is greatly influenced by the stereoregularity ratio. For example, in a case of P3HT, it has been reported that mobility at a stereoregularity ratio of 96% to 97% is on the order of 10⁻² cm²/Vs, mobility at a stereoregularity ratio of about 75% is on the order of 10⁻⁴ cm²/Vs, and mobility at a stereoregularity ratio of 75% is on the order of 10⁻⁵ cm²/Vs (Sirringhaus et.al, Nature, 401(1999) 685). The mobility and the diffusion coefficient are linked by the following Einstein relation using a Boltzmann constant (k), a temperature (T), and an elementary charge (q).

$$\begin{matrix}[ Math . 2 ] & \\ D = \frac{kT}{q} μ & ( 2 )\end{matrix}$$

It has been reported from several research institutions (for example, C. Vijila, J. Applied Physics 114,184503 (2013), B. Yang et.al, J. Phys. Chem. C, 118 (2014) 5196) that the carrier lifetime of the organic photoelectric conversion layer is examined by time-resolved spectroscopic measurement or alternating current impedance measurement, and is from several μsec to several tens of μsec depending on a device configuration and fabrication conditions.

Assuming that the carrier lifetime is 10 μsec, in a case where the mobility is 10⁻² cm²/Vs, the diffusion length is about 500 nm by the foregoing mathematical expressions (1) and (2), which is extremely larger than the film thickness that is from 50 nm to 300 nm of the organic photoelectric conversion layer; therefore, it is considered that the carriers are collectable by an electrode. Next, It is considered that under a similar assumption, in a case where the mobility is 10⁻⁴ cm²/Vs, the diffusion length is about 50 nm, and in a case where the film thickness of the organic photoelectric conversion layer is 50 nm, the carriers are collectable by the electrode; however, in a case where the film thickness is thicker than 50 nm, the carriers are deactivated before being collected by the electrode, thereby resulting in deterioration in photoelectric conversion efficiency. Moreover, under a similar assumption, in a case where the mobility is 10⁻⁵ cm²/Vs, the diffusion length is about 16 nm. In other words, it is considered that the diffusion length is smaller than the film thickness that is from 50 nm to 300 nm of the organic photoelectric conversion layer; therefore, the carriers are deactivated before being collected by the electrode, thereby resulting in deterioration in photoelectric conversion efficiency. Accordingly, it is considered that at least 10⁻⁴ cm²/Vs is necessary for the mobility of the conjugated polymer. In order to achieve this mobility, for example, in a case of P3HT, stereoregularity of about 75% or more is necessary. For the above reason, the lower limit of the stereoregularity ratio in the present disclosure is 75%.

The cross-sectional configuration of the photoelectric conversion layer in each of the experimental example 6 and the experimental example 8 was observed with use of a transmission electron microscope. It is possible to observe lattice fringes corresponding to a P3HT (100) plane with use of a high resolution transmission electron microscope. It is to be noted that in a case where lattice fringes of the P3HT (100) plane is seen parallel to the substrate, it is interpretable that Edge-on oriented P3HT is present in that portion. In a case where the lattice fringes of the P3HT (100) plane is seen perpendicular to the substrate, Face-on oriented P3HT is present in that portion. Alternatively, it is interpretable that a plane formed by a main chain of P3HT is oriented in a direction perpendicular to the substrate.

In the experimental example 8, the photoelectric conversion layer was formed with use of one kind of P3HT (P3HT-1 having a stereoregularity ratio of 99%) and PCBM. In this experimental example 8, almost all lattice fringes of the P3HT (100) plane were observed in a region of about 20 nm in proximity to the upper electrode and a region of about 20 nm in proximity to the lower electrode, and the orientation of the lattice fringes of the P3HT (100) plane were parallel to the substrate. It was found from this that a large amount of P3HT-1 was present in proximity to the upper electrode and the lower electrode of the photoelectric conversion layer in the experimental example 8, and the P3HT-1 was Edge-on oriented. Moreover, lattice fringes, oriented both parallel and perpendicular to the substrate, of the P3HT (100) plane were slightly observed in an internal region (a region of a bulk film) in a thickness direction of the photoelectric conversion layer; therefore, it was found that Edge-on oriented P3HT-1 and P3HT-1 that was Face-on oriented (or heterocycles configuring a main chain of P3HT were oriented in a direction perpendicular to the substrate) were mixed in the region of the bulk film.

In the experimental example 6, the photoelectric conversion layer was formed with use of two kinds of P3HTs (P3HT-1 having a stereoregularity ratio of 99% and P3HT-4 having a stereoregularity ratio of 90%) and PCBM. In this experimental example 6, many lattice fringes parallel to the substrate of the P3HT (100) plane were observed in a region of about 20 nm in proximity to the upper electrode. It was found from this that P3HT in proximity to the upper electrode was Edge-on oriented. In contrast, lattice fringes, oriented both parallel and perpendicular to the substrate, of the P3HT (100) plane were observed in a region of about 20 nm in proximity to the lower electrode. It was found from this that Edge-on oriented P3HT and P3HT that was Face-on oriented (or heterocycles configuring the main chain of P3HT were oriented in the direction perpendicular to the substrate) were mixed in proximity to the lower electrode. It is to be noted that even in the experimental example 6, as with the experimental example 8, lattice fringes, oriented both parallel and perpendicular to the substrate, of the P3HT (100) plane were observed in the internal region (the region of the bulk film) in the thickness direction of the photoelectric conversion layer. Therefore, it was found that both Edge-on oriented P3HT and P3HT that was Face-on oriented (or heterocycles configuring the main chain of P3HT were oriented in the direction perpendicular to the substrate) were mixed in the region of the bulk film.

In other words, this indicates that a combination of two kinds of P3HTs having different stereoregularities caused a decrease in Edge-on oriented P3HT that was disadvantageous in carrier transport in the vertical direction and an increase in Face-on oriented P3HT that was advantageous in carrier transport in the vertical direction. This result is consistent with the XRD intensity ratios of the experimental example 6 and the experimental example 8 shown in Table 1.

In the experimental example 6, the experimental example 8, and the experimental example 10, an element distribution in the thickness direction of the photoelectric conversion layer by time-of-flight secondary ion mass spectrometry was observed. Specifically, the mass number of molecules emitted by ionization while etching the photoelectric conversion device in a direction where respective layers were stacked by a gas cluster ion beam was measured with use of film time-of-flight secondary ion mass spectrometry (TOF-SIMS). Thus, an element profile in the thickness direction of the photoelectric conversion layer was obtained. As detection fragments, C₆₀ and C₇₂H₁₄O₂ derived from PCBM, and S and C₄HS derived from P3HT were used.

It was found from a result of TOF-SIMS measurement, in each of the experimental example 6, the experimental example 8, and the experimental example 10, concentrations of P3HT and PCBM in the bulk film were constant. Moreover, it was found that in each of the experimental example 6, the experimental example 8, and the experimental example 10, P3HT was highly concentrated at an upper electrode interface. This is consistent with the result in which a large amount of P3HT was present in proximity the upper electrode. It is to be noted that in a transmission electron microscope image in the experimental example 8, a large amount of P3HT observed in proximity to the lower electrode was not clearly discriminable from this result, but it is considered that this is caused by nonuniform excavation by the gas cluster ion beam.

### Experiment 2

As an experiment 2, samples (experimental examples 13 to 19) in which a mixture ratio of two kinds of P3HTs having different head-to-tail coupling stereoregularities was changed were fabricated, and short-circuit current density under irradiation with simulated solar light was measured.

### Experimental Example 13

First, a glass substrate provided with an ITO electrode (a lower electrode) was cleaned by UV/ozone treatment, and the substrate was coated with a poly(3,4-ethylenedioxythiophene)-poly(4-styrenesulfonate) solution (manufactured by Aldrich) by a spin coating method. Thereafter, the glass substrate was heated by a hot plate at 180° C. for 10 minutes. Thus, a hole transport layer having a film thickness of about 30 nm was formed. Next, the organic semiconductor materials P3HT-1 (having a weight average molecular weight of 47000 and a stereoregularity ratio of 99%) and P3HT-3 (having a weight average molecular weight of 97000 and a stereoregularity ratio of 90%) that each had head-to-tail coupling stereoregularity were used to prepare a chlorobenzene solution including P3HT-1, P3TH-3, and PCBM at a weight ratio of 50:0:50 and a concentration of 35 mg/ml in a N2-substituted glovebox. Next, the ITO electrode on which the hole transport layer was formed was coated with this chlorobenzene solution by a spin coating method, and thereafter was heated by a hot plate at 140° C. for 10 minutes to form the photoelectric conversion layer. A film thickness thereof was about 250 nm. Next, the substrate was moved into a vacuum evaporator, pressure was reduced to 1×10⁻⁵ Pa or less, and an AlSiCu alloy was evaporated to form a film having thicknesses of 100 nm. Thus, an upper electrode was formed. A photoelectric conversion device (the experimental example 13) having a 2 mm×2 mm photoelectric conversion region was fabricated by the above fabricating method.

### Experimental Example 14

A photoelectric conversion device (the experimental example 14) was fabricated with use of a method similar to the experimental example 13, except that a weight ratio of P3HT-1, P3HT-4, and PCBM was 45:5:50.

### Experimental Example 15

A photoelectric conversion device (the experimental example 15) was fabricated with use of a method similar to the experimental example 13, except that a weight ratio of P3HT-1, P3HT-4, and PCBM was 35:15:50.

### Experimental Example 16

A photoelectric conversion device (the experimental example 16) was fabricated with use of a method similar to the experimental example 13, except that a weight ratio of P3HT-1, P3HT-4, and PCBM was 25:25:50.

### Experimental Example 17

A photoelectric conversion device (the experimental example 17) was fabricated with use of a method similar to the experimental example 13, except that a weight ratio of P3HT-1, P3HT-4, and PCBM was 15:35:50.

### Experimental Example 18

A photoelectric conversion device (the experimental example 18) was fabricated with use of a method similar to the experimental example 13, except that a weight ratio of P3HT-1, P3HT-4, and PCBM was 5:45:50.

### Experimental Example 19

A photoelectric conversion device (the experimental example 19) was fabricated with use of a method similar to the experimental example 13, except that a weight ratio of P3HT-1, P3HT-4, and PCBM was 0:50:50.

Current-voltage characteristics under irradiation with simulated solar light of the photoelectric conversion devices in the foregoing experimental examples 13 to 19 were evaluated. Specifically, a bias was swept between the lower electrode and the upper electrode of the photoelectric conversion device under irradiation with simulated solar light of AM1.5G and 100 mW/cm² at a room temperature of 25° C. to obtain a current-voltage curve, and short-circuit current density was measured. Table 2 summarizes the p-type semiconductor materials and the n-type semiconductor material used in the experimental examples 13 to 19 and mixture ratios thereof, and measurement results of the short-circuit current density.

TABLE 2

| | | | | | Short-circuit |
|---|---|---|---|---|---|
| | P-type Semiconductor | | n-type | Mixture Ratio | Current Density |
| | p1 | p2 | Semiconductor | (p1:p2:n) | (mA/cm²) |
| Experimental | P3HT-1 | P3HT-4 | PCBM | 50:0:50 | 10.5 |
| Example 13 | rr = 99 | rr = 90% | | | |
| Experimental | Mw = 47k | Mw = 75k | | 45:5:50 | 10.8 |
| Example 14 | | | | | |
| Experimental | | | | 35:15:50 | 11.5 |
| Example 15 | | | | | |
| Experimental | | | | 25:25:50 | 13.1 |
| Example 16 | | | | | |
| Experimental | | | | 15:35:50 | 11.7 |
| Example 17 | | | | | |
| Experimental | | | | 5:45:50 | 9.81 |
| Example 18 | | | | | |
| Experimental | | | | 0:50:50 | 10.3 |
| Example 19 | | | | | |

In the experimental examples 13 to 19, a composition ratio (weight ratio) of P3HT-1 having a stereoregularity ratio of 99% and P3HT-4 having a stereoregularity ratio of 90% that configured the photoelectric conversion layer was changed within a range from 50:0 to 0:50. In a case where a comparison was made between the experimental examples 13 and 19 in which one of P3HT-1 and P3HT-4 was used alone and the experimental examples 14 to 18 in which a mixture of the P3HT-1 and P3HT-4 was used, it was found that using a mixture of P3HT-1 and P3HT-4 made it possible to achieve high short-circuit current density. Moreover, among the experimental examples 14 to the experimental example 18 in which the mixture was used, using a mixture of respective fixed or more amounts (for example, 30 wt % or more) of P3HT-1 and P3HT-4 made it possible to achieve higher short-circuit current density, and mixing P3HT-1 and P3HT-4 at a ratio (weight ratio) of 1:1 made it possible to achieve the highest short-circuit current density. In other words, it was found that each of P3HT having a stereoregularity ratio of 95% and P3HT having a stereoregularity ratio of 75% or more but less than 95% used in the photoelectric conversion layer was preferably from 30 wt% to 70 wt % both inclusive. It is assumed that this result was caused because mixing P3HTs having different stereoregularities caused an increase in Face-on oriented P3HT that was advantageous in carrier transport in the vertical direction and a decrease in Edge-on oriented P3HT that was disadvantageous in carrier transport in the vertical direction, as described in the results of XRD of the experimental examples 1 to 7 in the experiment 1.

### Experiment 3

As an experiment 3, samples (experimental examples 20 to 23) in which a weight ratio of the p-type semiconductor and the n-type semiconductor configuring the photoelectric conversion layer was changed were fabricated, and short-circuit current density thereof was measured. It is to be noted that herein, as the p-type semiconductor, P3HT-3 having a stereoregularity ratio of 99% and P3HT-4 having a stereoregularity ratio of 90% were used, and a weight ratio thereof was 1:1, The short-circuit current density was measured with use of a method similar to that in the experiment 2. Table 3 summarizes the p-type semiconductor materials and n-type semiconductor material used in the experimental examples 20 to 23 and mixture ratios thereof, and measurement results of the short-circuit current density.

### Experimental Example 20

A photoelectric conversion device (the experimental example 20) was fabricated with use of a method similar to the experimental example 13, except that a weight ratio of P3HT-1, P3HT-4, and PCBM was 37.5:37.5:25.

### Experimental Example 21

A photoelectric conversion device (the experimental example 21) was fabricated with use of a method similar to the experimental example 13, except that a weight ratio of P3HT-1, P3HT-4, and PCBM was 40:40:20.

### Experimental Example 22

A photoelectric conversion device (the experimental example 22) was fabricated with use of a method similar to the experimental example 13, except that a weight ratio of P3HT-1, P3HT-4, and PCBM was 12.5:12.5:75.

### Experimental Example 23

A photoelectric conversion device (the experimental example 23) was fabricated with use of a method similar to the experimental example 13, except that a weight ratio of P3HT-1, P3HT-4, and PCBM was 10:10:80.

TABLE 3

| | | | | | Short-circuit |
|---|---|---|---|---|---|
| | P-type Semiconductor | | n-type | Mixture Ratio | Current Density |
| | p1 | p2 | Semiconductor | (p1:p2:n) | (mA/cm²) |
| Experimental | P3HT-1 | P3HT-4 | PCBM | 37.5:37.5:25 | 4.2 |
| Example 20 | rr = 99% | rr = 90% | | | |
| Experimental | Mw = 47k | Mw = 75k | | 40:40:20 | 2.1 |
| Example 21 | | | | | |
| Experimental | | | | 12.5:12.5:75 | 3.2 |
| Example 22 | | | | | |
| Experimental | | | | 10:10:80 | 1.4 |
| Example 23 | | | | | |

The experimental example 20 in which the weight ratio of the p-type semiconductor and the n-type semiconductor was 75:25 achieved higher short-circuit current density than that in the experimental example 21 in which the weight ratio of the p-type semiconductor and the n-type semiconductor was 80:20. The experimental example 22 in which the weight ratio of the p-type semiconductor and the n-type semiconductor was 25:75 achieved higher short-circuit current density than that in the experimental example 23 in which the weight ratio of the p-type semiconductor and the n-type semiconductor was 20:80. This indicates that the weight ratio of the p-type semiconductor and the n-type semiconductor was preferably within a range from 25:75 to 75:25.

It is to be noted that it is possible to analyze head-to-tail coupling stereoregularity by, for example, the following method. For example, it is possible to calculate stereoregularity of 3-substituted polythiophene (P3HT) by a ratio of a signal of an a-methylene proton of an alkyl group attached to a thiophene ring obtained by ¹H-NMR. Specifically, stereoregularity is measured by ¹H-NMR (500 MHz, a CDC13 solvent, TMS standard) to obtain signals belonging the a-methylene proton of the alkyl group bound to the thiophene ring in a head-to-tail coupling fashion and a head-to-head coupling fashion respectively around 2.80 ppm and 2.58 ppm. It is possible to calculate, as head-to-tail coupling stereoregularity, a value resulting from dividing an integral value of the former signal by the sum of integral values of the former signal and the latter signal and multiplying a result of such division by 100.

Moreover, in a case where the photoelectric conversion layer includes a mixture of high molecular compounds having different stereoregularity ratios, it is possible to analyze the stereoregularity ratio by the following method. Analysis of the stereoregularity ratio by an NMR method gives an average value of all samples; therefore, it is difficult to obtain information whether or not the mixture is included. In such a case, the mixture is separated by liquid chromatography, and thereafter, the NMR method is used. This allows for the analysis. It is possible to separate the mixture of the high molecular compounds by liquid chromatography using size exclusion, adsorption-desorption, and a precipitation-dissolution mechanism. It is to be noted that in a case where the molecular weights thereof are completely the same, it is difficult to perform separation by a size exclusion mechanism, but if there is a difference in stereoregularity, solubility is different. Accordingly, a separation method using the precipitation-dissolution mechanism is effective.

Although the description has been given by referring to the first and second embodiments and the examples, the contents of the present disclosure are not limited to the foregoing embodiments, etc., and may be modified in a variety of ways. For example, the organic photoelectric conversion layer 14, etc. may include three or more kinds of the foregoing organic semiconductor materials having head-to-tail coupling stereoregularity.

Moreover, the foregoing embodiments, etc. have exemplified the configuration of the imaging device of the back-side illumination type; however, the contents of the present disclosure are applicable to an imaging device of a front-side illumination type. Further, it may not be necessary for the photoelectric conversion devices 10 and 20 and the imaging device 30 of the present disclosure to include all components described in the foregoing embodiments, or the photoelectric conversion devices 10 and 20 and the imaging device 30 of the present disclosure may include any other layer.

It is to be noted that the effects described in the present specification are illustrative and non-limiting, and other effects may be included.

It is to be noted that the present disclosure may have the following configurations.

[1]

A photoelectric conversion device, including:

a first electrode and a second electrode facing each other; and

a photoelectric conversion layer provided between the first electrode and the second electrode, and including a first organic semiconductor having head (Head)-to-tail (Tail) coupling stereoregularity of 95% or more represented by the following formula (1) and a second organic semiconductor having head-to-tail coupling stereoregularity of 75% or more but less than 95% represented by the following formula (1),

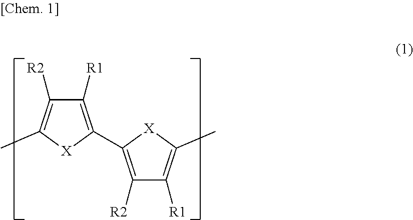

(where R1 and R2 are different from each other, and each are a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof, X is one of chalcogen atoms (oxygen (O), sulfur (S), selenium (Se) and tellurium (Te)) and Group V atoms (nitrogen (N) and phosphorus(P)).)
[2]

The photoelectric conversion device according to [1], in which an average molecular weight of the first organic semiconductor material is from 5000 to 150000 both inclusive.

[3]

The photoelectric conversion device according to [1] or [2], in which

the first organic semiconductor material and the second organic semiconductor material serve as a p-type semiconductor material, and

the photoelectric conversion layer includes a fullerene derivative as an n-type semiconductor material.

[4]

The photoelectric conversion device according to [3], in which the first organic semiconductor material is included in the photoelectric conversion layer, and is included at a ratio of 10 wt % or more of the p-type semiconductor material having head-to-tail coupling stereoregularity represented by the formula (1).

[5]

The photoelectric conversion device according to [3], in which the first organic semiconductor material is included in the photoelectric conversion layer, and is included at a ratio of 30 wt % to 70 wt % both inclusive of the p-type semiconductor material having head-to-tail coupling stereoregularity represented by the formula (1).

[6]

The photoelectric conversion device according to any one of [3] to [5], in which a weight ratio of the p-type semiconductor material and the n-type semiconductor material included in the photoelectric conversion layer is within a range from 25:75 to 75:25.

[7]

The photoelectric conversion device according to any one of [1] to [6], in which a semiconductor substrate is provided as the first electrode, and the photoelectric conversion layer is formed on a side on which a first surface is located of the semiconductor substrate.

[8]

The photoelectric conversion device according to [7], in which a multilayer wiring layer is formed on a side on which a second surface is located of the semiconductor substrate.

[9]

A imaging unit provided with pixels each including one or a plurality of photoelectric conversion devices, each of the photoelectric conversion devices including:

a first electrode and a second electrode facing each other; and

a photoelectric conversion layer provided between the first electrode and the second electrode, and including a first organic semiconductor having head (Head)-to-tail (Tail) coupling stereoregularity of 95% or more represented by the following formula (1) and a second organic semiconductor having head-to-tail coupling stereoregularity of 75% or more but less than 95% represented by the following formula (1),

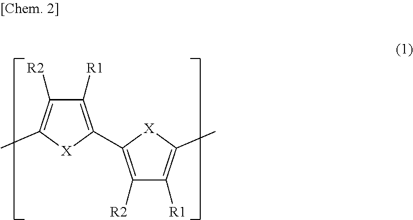

(where R1 and R2 are different from each other, and each are a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof, X is one of chalcogen atoms (oxygen (O), sulfur (S), selenium (Se) and tellurium (Te)) and Group V atoms (nitrogen (N) and phosphorus(P)).)

This application claims the benefit of Japanese Priority Patent Application JP2015-256622 filed with the Japan Patent Office on Dec. 28, 2015 and Japanese Priority Patent Application JP2016-048540 filed with the Japan Patent Office on Mar. 11, 2016, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A photoelectric conversion device, comprising:
a first electrode and a second electrode facing each other; and
a photoelectric conversion layer provided between the first electrode and the second electrode, and including a first organic semiconductor having head (Head)-to-tail (Tail) coupling stereoregularity of 95% or more represented by the following formula (1) and a second organic semiconductor having head-to-tail coupling stereoregularity of 75% or more but less than 95% represented by the following formula (1), 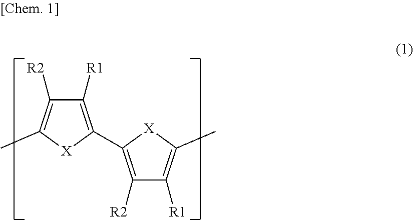
(where R1 and R2 are different from each other, and each are a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof, X is one of chalcogen atoms (oxygen (O), sulfur (S), selenium (Se) and tellurium (Te)) and Group V atoms (nitrogen (N) and phosphorus(P)).)

2. The photoelectric conversion device according to claim 1, wherein an average molecular weight of the first organic semiconductor material is from 5000 to 150000 both inclusive.

3. The photoelectric conversion device according to claim 1, wherein
the first organic semiconductor material and the second organic semiconductor material serve as a p-type semiconductor material, and
the photoelectric conversion layer includes a fullerene derivative as an n-type semiconductor material.

4. The photoelectric conversion device according to claim 3, wherein the first organic semiconductor material is included in the photoelectric conversion layer, and is included at a ratio of 10 wt % or more of the p-type semiconductor material having head-to-tail coupling stereoregularity represented by the formula (1).

5. The photoelectric conversion device according to claim 3, wherein the first organic semiconductor material is included in the photoelectric conversion layer, and is included at a ratio of 30 wt % to 70 wt % both inclusive of the p-type semiconductor material having head-to-tail coupling stereoregularity represented by the formula (1).

6. The photoelectric conversion device according to claim 3, wherein a weight ratio of the p-type semiconductor material and the n-type semiconductor material included in the photoelectric conversion layer is within a range from 25:75 to 75:25.

7. The photoelectric conversion device according to claim 1, wherein a semiconductor substrate is provided as the first electrode, and the photoelectric conversion layer is formed on a side on which a first surface is located of the semiconductor substrate.

8. The photoelectric conversion device according to claim 7, wherein a multilayer wiring layer is formed on a side on which a second surface is located of the semiconductor substrate.

9. A imaging unit provided with pixels each including one or a plurality of photoelectric conversion devices, each of the photoelectric conversion devices comprising:
a first electrode and a second electrode facing each other; and
a photoelectric conversion layer provided between the first electrode and the second electrode, and including a first organic semiconductor having head (Head)-to-tail (Tail) coupling stereoregularity of 95% or more represented by the following formula (1) and a second organic semiconductor having head-to-tail coupling stereoregularity of 75% or more but less than 95% represented by the following formula (1), 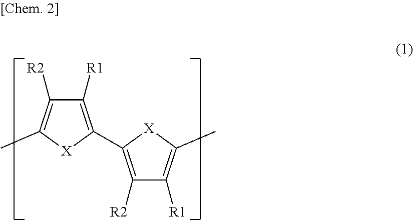
(where R1 and R2 are different from each other, and each are a halogen atom, a straight-chain, branched, or cyclic alkyl group, a phenyl group, a group having a straight-chain or condensed ring aromatic compound, a group having a halide, a partial fluoroalkyl group, a perfluoroalkyl group, a silylalkyl group, a silyl alkoxy group, an arylsilyl group, an arylsulfanyl group, an alkylsulfanyl group, an arylsulfonyl group, an alkylsulfonyl group, an arylsulfide group, an alkylsulfide group, an amino group, an alkylamino group, an arylamino group, a hydroxy group, an alkoxy group, an acylamino group, an acyloxy group, a carbonyl group, a carboxy group, a carboxyamide group, a carboalkoxy group, an acyl group, a sulfonyl group, a cyano group, a nitro group, a group having a chalcogenide, a phosphine group, a phosphone group, or a derivative thereof, X is one of chalcogen atoms (oxygen (O), sulfur (S), selenium (Se) and tellurium (Te)) and Group V atoms (nitrogen (N) and phosphorus(P)).)
